(19) United States
(12) Patent Application Publication
(10) Pub. No.: US 2023/0209845 A1
(43) Pub. Date: Jun. 29, 2023

(54) ENHANCING THE LIFETIME OF MOLECULAR AND MOLECULAR SALT PHOTOVOLTAICS & LUMINESCENT SOLAR CONCENTRATORS

(71) Applicant: Board of Trustees of Michigan State University, East Lansing, MI (US)

(72) Inventors: Richard Royal LUNT, III, Williamston, MI (US); Christopher HERRERA, Haslett, MI (US); Chenchen YANG, Holt, MI (US); Aria VAHDANI, East Lansing, MI (US); Babak BORHAN, Okemos, MI (US)

(21) Appl. No.: 18/108,861

(22) Filed: Feb. 13, 2023

Related U.S. Application Data
(63) Continuation-in-part of application No. 16/765,625, filed on May 20, 2020, now abandoned.
(60) Provisional application No. 62/594,839, filed on Dec. 5, 2017.

(51) Int. Cl. H10K 30/30; H10K 30/82; H10K 30/87; H10K 85/60

(52) U.S. Cl. CPC H10K 30/30; H10K 30/82; H10K 30/87; H10K 85/6572

(57) ABSTRACT

A solar panel includes a substrate and a photoactive material. The photoactive material includes an ion and a counterion. An absolute magnitude of a binding energy between the ion and the counterion is less than or equal to about 6.5. A majority of available hydrogen sites on the counterion may be halogenated. A water contact angle of the photoactive material may be greater than or equal to about 65°. The solar panel may be a photovoltaic or a luminescent solar concentrator.

### CROSS-REFERENCE TO RELATED APPLICATIONS

This application is a continuation-in-part of U.S. application Ser. No. 16/765,625, filed May 20, 2020, which is a 371 U.S. National Phase of International Application No. PCT/US2018/064010, filed Dec. 5, 2018, which claims priority to U.S. Provisional Application No. 62/594,839, filed on Dec. 5, 2017. The entire disclosures of the above applications are incorporated herein by reference.

### GOVERNMENT RIGHTS

This invention was made with government support under 1254662 and 1511098 awarded by the National Science Foundation and under 000115873 awarded by the U.S. Department of Education. The government has certain rights in the invention.

### FIELD

The present disclosure relates to enhancing the lifetime of organic and organic salt photovoltaics.

### BACKGROUND

This section provides background information related to the present disclosure which is not necessarily prior art.

Highly transparent photovoltaics (HTPVs) can enable new routes to solar deployment on building windows, automobiles, electronic displays, and virtually any other surface without aesthetic compromise. While high device performance and visible transmission are critical for many of these new commercial deployment routes, application-specific lifetime is equally important because it largely determines installation feasibility and total power output. Although the longest achievable lifetimes remain one of the major goals of PV research, it is also important in practical distribution to match technologies to their precise applications. Understanding the effects of molecular structure and composition on the stability of wavelength selective photoactive materials is therefore key to enabling wide-scale HTPV deployment.

HTPVs have incorporated NIR-selective organic small molecules, polymers, and molecular salts as donor materials. While a large range of small molecules and polymers have been developed for many years, NIR-selective molecular salts have only recently been investigated in earnest for organic photovoltaic (OPV) devices. It has been shown that exchanging the anion shifts the frontier orbital energies, and thus, the highest occupied molecular orbital (HOMO) and lowest unoccupied molecular orbital (LUMO) of the collective salt, without significantly affecting absorption or bandgap. This can enable the rapid optimization of the interface gap (donor HOMO and acceptor LUMO offset) and open circuit voltage (V_{oc}) with virtually any given acceptor. Physical properties such as solubility and surface energies can similarly be tailored with various anions. Optical absorption can then be tuned independently via conjugation of the cation, which has allowed efficient NIR photoresponse as deep as 1600 nm.

Molecular and organic semiconductors utilized to fabricate HTPVs are often considered to have inherently low stability compared to inorganic technologies due to a tendency to react with oxygen and moisture. However, encapsulation alone can alleviate many of the stability issues with OPVs and organic light emitting diodes, so that devices retain high performance for many years. Recent organic demonstrations with reported extrapolated device lifetimes of greater than 20 years provide a clear indication that OPV technologies can be just as viable for long-term applications as inorganic technologies, even though most reports demonstrate extrapolated and non-extrapolated lifetimes of about 2 years and less than 1.5 years, respectively.

Although the properties of photoactive layers, transport layers, and electrodes, have previously been correlated to OPV lifetime, little work has focused explicitly on NIR wavelength selective photoactive materials with bandgaps applicable to HTPVs. Accordingly, there remains a need to develop methods for extending lifetimes of photovoltaic devices and to develop photovoltaic devices having extended lifetimes.

### SUMMARY

This section provides a general summary of the disclosure, and is not a comprehensive disclosure of its full scope or all of its features.

At least one example embodiment relates to a solar panel including a substrate and a photoactive material. The photoactive material includes an ion and a counterion. An absolute magnitude of a binding energy between the ion and the counterion is less than or equal to about 6.5.

In at least one example embodiment, the absolute magnitude of the binding energy is less than or equal to about 5.

In at least one example embodiment, a majority of available hydrogen sites on the counterion are halogenated.

In at least one example embodiment, the counterion is fully halogenated.

In at least one example embodiment, a water contact angle of the photoactive material is greater than or equal to about 65°.

In at least one example embodiment, the water contact angle is greater than or equal to about 75°.

In at least one example embodiment, the solar panel has a lifetime T₅₀ of greater than or equal to about 500 hours.

In at least one example embodiment, the lifetime T₅₀ is greater than or equal to about 5,000 hours.

In at least one example embodiment, the ion is heptamethine cyanine.

In at least one example embodiment, the ion is selected from the group consisting of: Cy7, Cy7m, Cy7NHS Ester, Cy5, Cy5m, Cy5NHS Ester, Cy7.5, Cy7.5m, Cy7.5NHS Ester, Cy3, Cy3m, Cy3NHS, or any combination thereof. The counterion is selected from the group consisting of: tetrafluoroborate, hexafluorophosphate, Δ-tris(tetrachloro-1,2-benzenediolato)phosphate(V), Δ-tris(tetrafluoro-1,2-benzenediolato)phosphate(V), Δ-tris(tetrabromo-1,2-benzenediolato)phosphate(V), Δ-tris(tetraiodo-1,2-benzenediolato)phosphate(V), Tris(pentafluoroethyl)silane, tetrakis[3,5-bis(trifluoromethyl)phenyl]borate (TFM), tetraphenylborate, tetrakis(4-fluorophenyl)borate, tetrakis(pentafluorophenyl)borate, tetrakis(pentachlorophenyl)borate, tetrakis(pentabromophenyl)borate, tetrakis(pentaiodophenyl)borate, Bis(trifluoromethanesulfonyl)imide (TFSI), Bis(fluorosulfonyl)-imide (FSI), Fluorosulfonyl(trifluoromethanesulfonyl)imide (FTFS), Trifluoromethanesulfonate (Tf), Perfluorobutanesulfonate (PFBS), bis[(pentafluoroethyl)sulfonyl]imide (BETI), 2,2,2-trifluoromethylsulfonyl-N-cyanoamide (TFSAM), 2,2,2-trifluoro-N-(trifluoromethylsulfonyl) acetamide (TSAC), nonafluorobutanesulfonate (NF), Tetracyanoborate, B(CN)₄, Dicyanamide (DCA), Thiocyanate (SCN), Cyclic perfluorosulfonylamide (CPFSA), Camphorsulfonate (CpSO₃), Tetrahalogenoferrate(III) (FeCl₃Br), Halogenchromate (CrO₃X, X=Cl, Br, I), Tetrachloroferrate (FeX₄, X=Cl, Br, I), Di(hydrogenfluoro)-fluoride ((FH)₂F), Tri(hydrogenfluoro)-fluoroide ((FH)₃F), Dihydrogen phosphate (DHP), Difluoro phosphate, Dichloro phosphate, tricyanomethanide, acetate, triflouroacetate, trichloroacetate, tribromoacetate, Si(SiCl₃)₃, and carboranes including: o-carborane, cobalticarborane (CoCB²⁻), CB₁₁H₁₂ (CBH), B₁₂F₁₂ (FCB), C₂B₉H₁₁, HCB₁₁H₁₁, HCB₉H₉, H₂NCB₁₁H₁₁, HCB₁₁H₅Cl₆, HCB₁₁H₅Br₆, C₅N₂B₂₂H₂₅, HCB₉Cl₉, HCB₉Cl₉, or any combination thereof.

In at least one example embodiment, the solar panel is a photovoltaic (PV). The PV includes a first electrode, the photoactive material, and the second electrode. The first electrode is on the substrate. The photoactive material is between the first electrode and the second electrode.

In at least one example embodiment, the solar panel is a luminescent solar concentrator (LSC). The LSC includes a waveguide and a photovoltaic device. The waveguide includes the substrate and the photoactive material. The photoactive material is in contact with the substrate. The photovoltaic device is coupled to the substrate.

In at least one example embodiment, the photoactive material is embedded in the substrate, present in a layer on a surface of the substrate, or both embedded and in a layer.

In at least one example embodiment, the photovoltaic device is coupled to an edge surface of the substrate.

In at least one example embodiment, at least one of the ion and the counterion is organic.

At least one example embodiment relates to a solar panel including a substrate and a photoactive material. The photoactive material includes an ion and a counterion. A majority of available hydrogen sites on the counterion are halogenated. The photoactive material has a water contact angle of greater than or equal to about 65°

In at least one example embodiment, the counterion is fully halogenated.

In at least one example embodiment, water contact angle is greater than or equal to about 75°.

In at least one example embodiment, the water contact angle is greater than or equal to about 80°.

In at least one example embodiment, the solar panel has a lifetime T₈₀ of greater than or equal to about 500 hours.

In at least one example embodiment, the lifetime T₈₀ is greater than or equal to about 2,000 hours.

In at least one example embodiment, the solar panel is a photovoltaic (PV). The PV includes a first electrode, the photoactive material, and the second electrode. The first electrode is on the substrate. The photoactive material is between the first electrode and the second electrode.

In at least one example embodiment, the solar panel is a luminescent solar concentrator (LSC). The LSC includes a waveguide and a photovoltaic device. The waveguide includes the substrate and the photoactive material. The photoactive material is in contact with the substrate. The photovoltaic device is coupled to the substrate.

At least one example embodiment relates to a method of fabricating a solar panel. The method includes selecting an photoactive material including an ion and a counterion. The method further includes determining whether a water contact angle of the photoactive material is greater than or equal to about 65°. The method further includes, when the water contact angle is not greater than or equal to about 65°, tuning the photoactive material until the water contact angle is greater than or equal to about 65°. The method further includes disposing the photoactive material having the water contact angle of greater than or equal 65° into a solar panel device. The solar panel device has a lifetime T₅₀ of greater than or equal to about 500 hours.

In at least one example embodiment, the method further includes determining a binding energy between the ion and the counterion. The method further includes determining whether an absolute magnitude of the binding energy is less than or equal to about 6.5. The method further includes, when the absolute magnitude of the binding energy is not less than or equal to about 6.5, tuning the photoactive material until the binding energy is less than or equal to about 6.5.

In at least one example embodiment, the tuning includes tuning the photoactive material until the binding energy is less than or equal to about 5.

In at least one example embodiment, the tuning includes tuning the photoactive material until the water contact angle is greater than or equal to about 75°.

In at least one example embodiment, the tuning includes substituting the counterion.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a schematic illustration of a first device according to various aspect of the present technology.

FIG. 1B is a schematic illustration of a second device according to various aspects of the present technology.

FIG. 10 is a schematic illustration of a third device according to various aspects of the present technology.

FIG. 2A shows the molecular structures for the heptamethine (Cy⁺) cation (top) and the anions paired with it: (1) TPFB⁻, (2) TRIS⁻, (3) TFM⁻, (4) PF₆⁻, and (5) I⁻.

FIG. 2B is the molecular structure for ClAlPc.

FIG. 2C shows the normalized extinction coefficients for each donor.

FIGS. 3A-3C are representative ClAlPc PHJ devices held at short circuit (FIG. 3A), open circuit (FIG. 3B), and maximum power point (MPP) (FIG. 3C). A significant difference in stability across these three loading conditions for any architecture is not observed.

FIGS. 4A-4D show normalized lifetime data for ClAlPc PHJ and PMHJ devices. J_{sc}, V_{oc}, FF, and PCE are shown in FIG. 4A, FIG. 4B, FIG. 4C, and FIG. 4D, respectively. Representative error bars denote the maximum standard deviations across all devices for each performance parameter.

FIGS. 5A-5D show normalized lifetime data for CyTPFB, CyTRIS, CyPF₆, Cyt, and CyTFM devices. J_{sc}, V_{oc}, FF, and PCE are shown in FIG. 5A, FIG. 5B, FIG. 5C, and FIG. 5D respectively. Representative error bars denote maximum standard deviations across all devices for each performance parameter.

FIGS. 6A-6B show champion PCE lifetime data for all ClAlPc (FIG. 6A) and molecular salt (FIG. 6B) architectures from FIGS. 4A-4D and FIGS. 5A-5D.

FIGS. 7A-7D show normalized EQE data measured from representative ClAlPc PHJ (FIG. 7A), ClAlPc PMHJ (FIG. 7B), CyPF₆ (FIG. 7C), and CyTPFB (FIG. 7D) devices during lifetime testing.

FIGS. 8A-8C are transmission spectra for CyTPFB (FIG. 8A), ClAlPc (PHJ) (FIG. 8B), and ClAlPc (PMHJ) (FIG. 8C) devices without top Ag electrodes measured before and after illumination.

FIGS. 9A-9F are representative photographs of water droplets on 50 nm films of CyTPFB (FIG. 9A), CyTRIS (FIG. 9B), ClAlPc:C₆₀ (FIG. 9C), Cyl (FIG. 9D), ClAlPc (FIG. 9E), and CyTFM (FIG. 9F), shown in order of decreasing hydrophobicity, from which contact angles were measured.

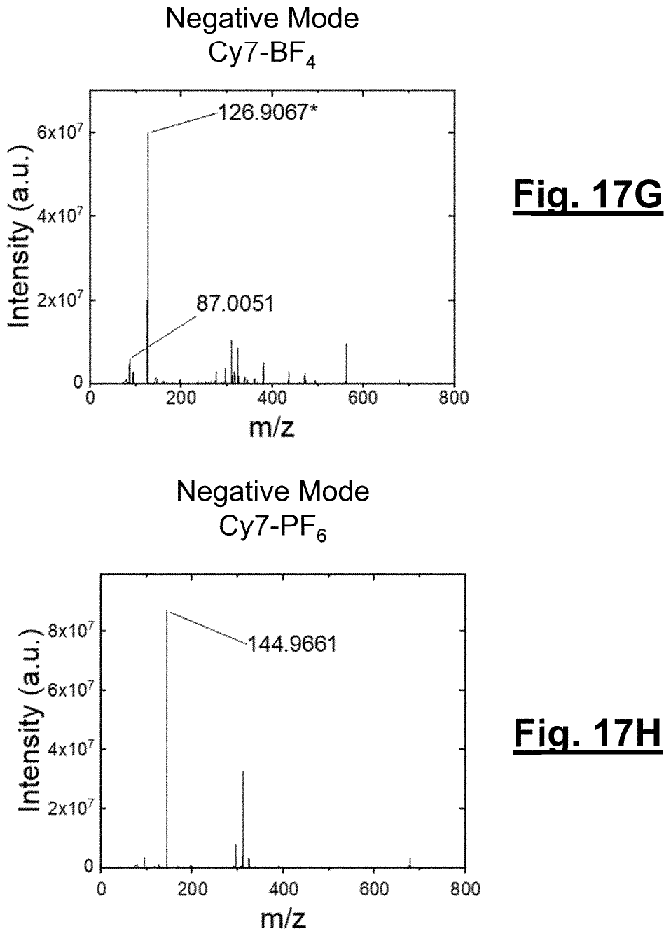

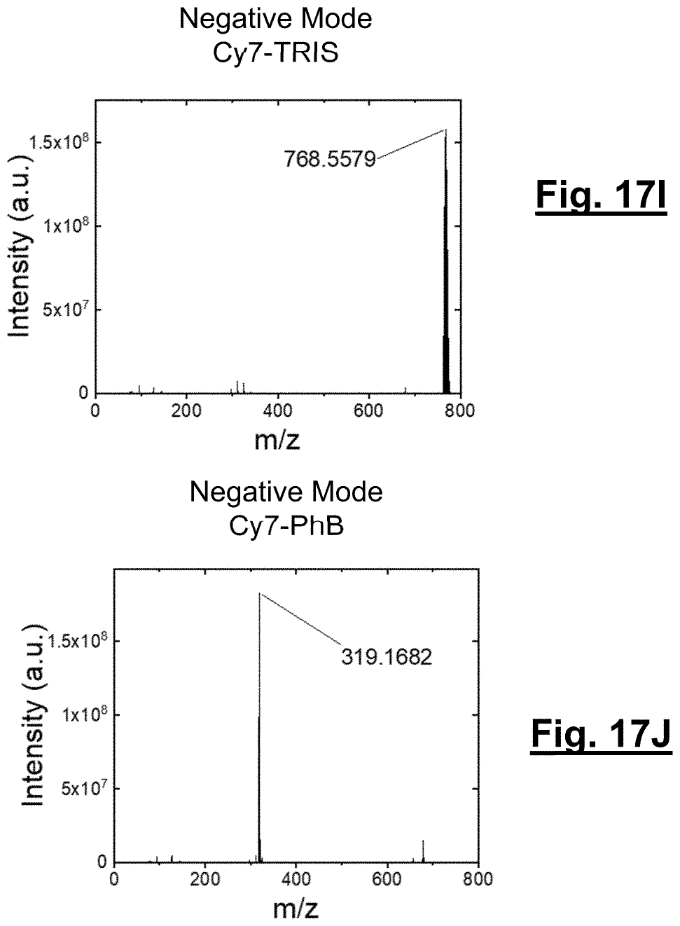

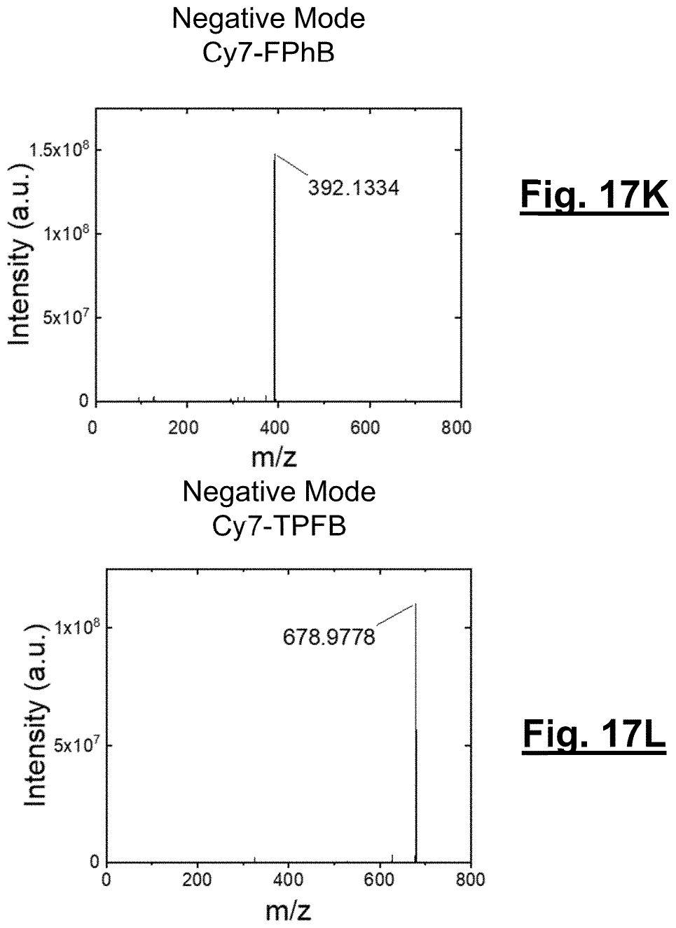

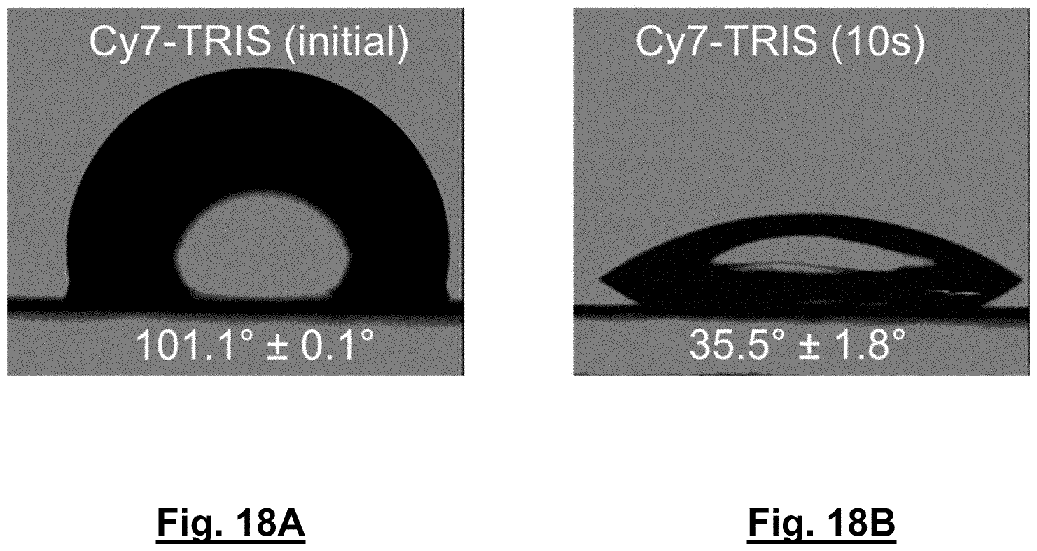

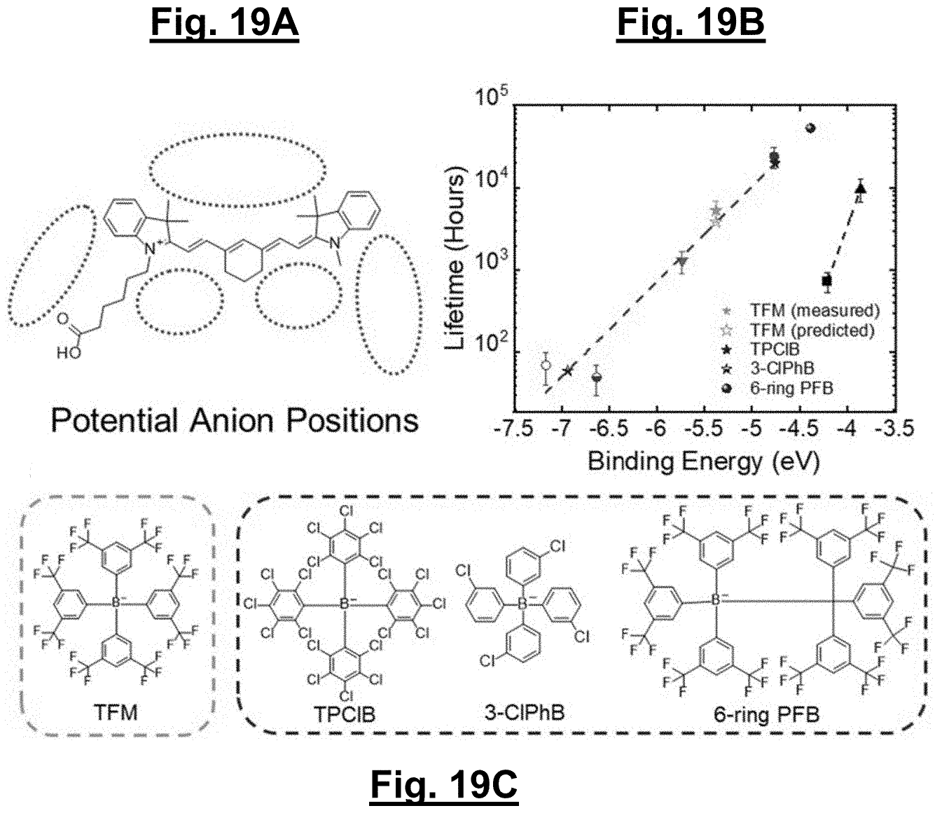

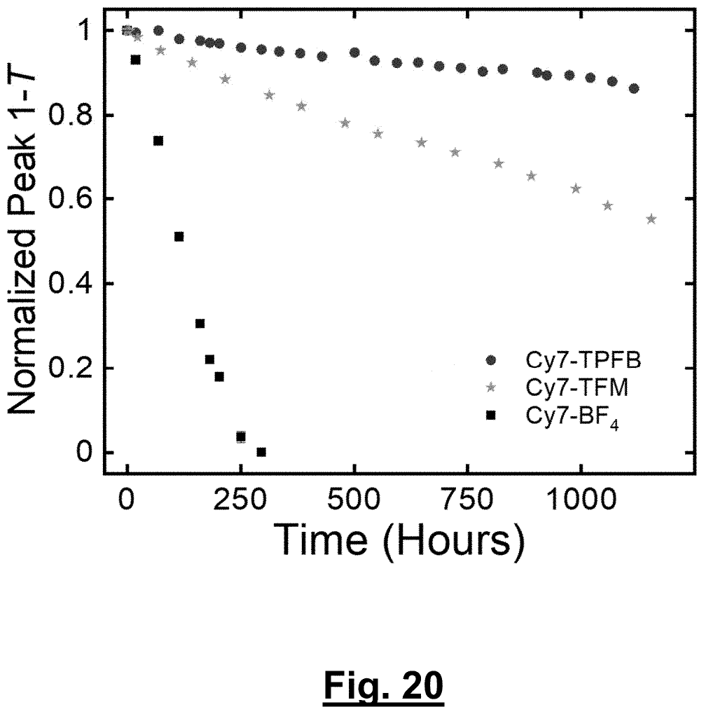

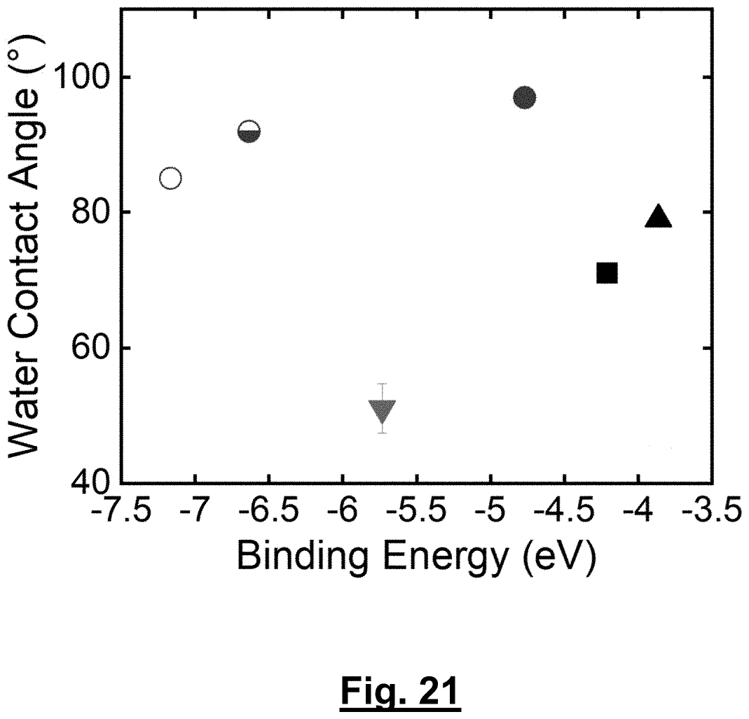

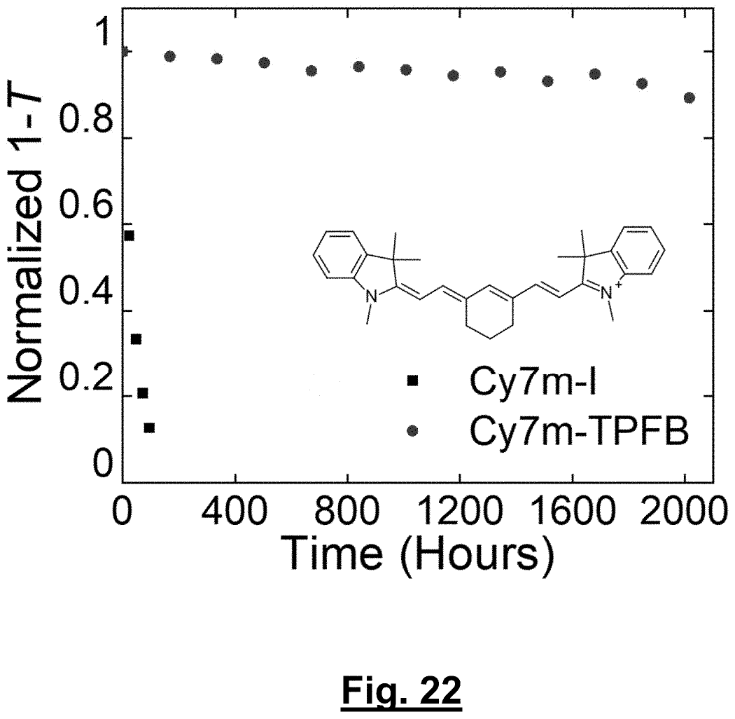

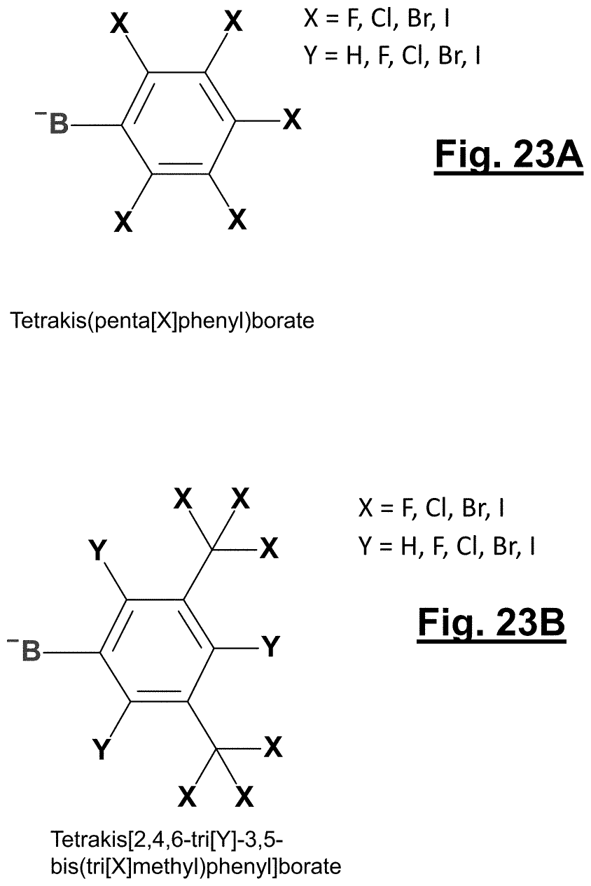

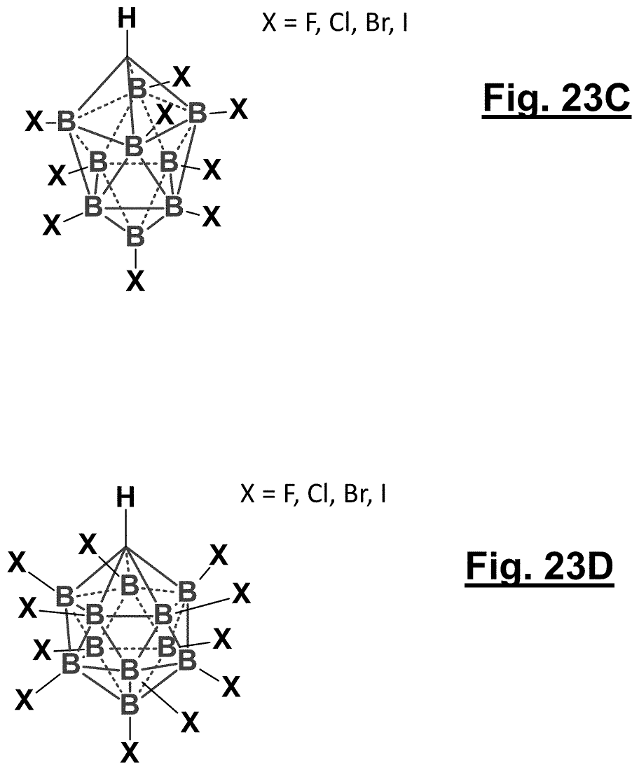

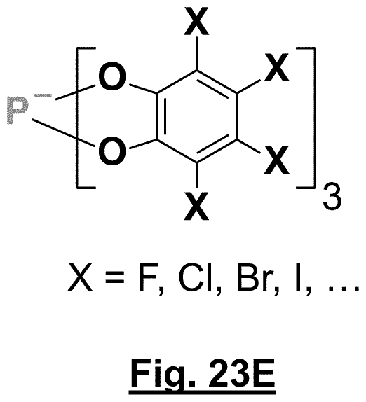

FIGS. 10A-10B are AFM images collected on CyTPFB (FIG. 10A) and CyTFM (FIG. 10B) films deposited from 12 mg/ml solutions over Si. The RMS roughnesses are 0.36±0.04 nm and 0.27±0.01 nm, respectively.

FIG. 11 shows champion lifetimes (T₅₀) plotted as a function of isolated donor film water contact angle for all devices. Lifetime is directly correlated to water contact angle for both vacuum deposited small molecule donor and solution deposited molecular salt devices.

FIGS. 12A-12B are are schematic illustrations of a transparent luminescent solar concentrator (TLSC) according to various aspects of the present technology. FIG. 12A depicts the TLSC. FIG. 12B shows light interacting with the TLSC of FIG. 12A in accordance with at least one example embodiment.

FIG. 13A is a schematic of a luminescent solar concentrator where incident solar irradiance is absorbed by a luminophore in the device. The light is then re-emitted in all directions where most will be waveguided to the edge-mounted solar cells via total internal reflection (TIR) while some light is lost to reabsorption or at angles too large for TIR. FIG. 13B is a graph illustrating normalized absorption (solid lines) and emission (dashed lines) spectra of two of the compounds in this study (Cy7-TPFBm and Cy7-BF₄). The narrow absorption and emission peak outside of the visible region of the solar spectrum. FIG. 13C is a schematic illustrating chemical structures cationic heptamethine cyanine dye (Cy7) (top left) paired with different anions, grouped within dashed boxes based on core design motif. The anions are shown as follows: (1) BF₄, (2) PF₆, (3) TRIS, (4) PhB, (5) FPhB, and (6) TPFB.

FIG. 14A is a graph illustrating normalized 1-transmittance (T) vs. time for each Cy7-anion pairing. T uncertainty is propagated from the device uncertainty of ±0.05%. FIG. 14B is a graph illustrating corresponding normalized peak external quantum efficiency (EQE) for each device measured weakly against hours under illumination. Samples that degraded fully within a day were not included in the EQE dataset. GIF. 14C is a graph illustrating calculated internal quantum efficiency (IQE) from dividing the EQE by the normalized absorption is show vs time. The IQE is representative of quantum yield (QY), showing how the QY remains constant as the absorption decays. The legend in FIG. 14A is also applicable to FIGS. 14B and 14C.

FIG. 15A is a graph illustrating 1-T for Cy7-BF₄. FIG. 15B is a graph illustrating 1-T for Cy7-PF₆. FIG. 15C is a graph illustrating 1-T for Cy7-TRIS. FIG. 15D is a graph illustrating 1-T for Cy7-PhB. FIG. 15E is a graph illustrating 1-T for Cy7-FPhB. FIG. 15F is a graph illustrating 1-T for Cy7-TPFB. FIG. 15G is a graph illustrating EQE for Cy7-BF₄. FIG. 15H is a graph illustrating EQE for Cy7-PF₆. FIG. 15I is a graph illustrating EQE for Cy7-TRIS. FIG. 15J is a graph illustrating EQE for Cy7-TPFB.

FIG. 16A is a graph illustrating water contact angle vs lifetime of each salt plotted on a semilogarithmic scale. Note that the lifetime was measured from a dilute film while the contact angle is from a neat film. FIG. 16B is a collection of images used to calculate the water contact angle of each salt, with photos being taken 10 seconds after dropping the water onto the film.

The salts were dissolved into acetonitrile and measured in mass spectrometry at molarities of 10 nM, 100 nM, and 1 μM. The displayed m/z plots above are from the 1 μM measurements prior to any degradation study for positive and negative scans. (*) indicates peaks that do not scale with concentration in the dilution set, indicating contaminants present in the original solvent or from the instrument.

FIGS. 17A-17F are positive scan mass spectra for the Cy7-anion pairings. FIG. 17A illustrates data for Cy7-BF₄. FIG. 17B illustrates data for Cy7-PF₆. FIG. 17C illustrates data for Cy7-TRIS. FIG. 17D illustrates data for Cy7-PhB. FIG. 17E illustrates data for Cy7-FPhB. FIG. 17F illustrates data for Cy7-TPFB. FIGS. 17G-17L are negative scan mass spectra for the Cy7-anion pairings. FIG. 17G illustrates data for Cy7-BF₄. FIG. 17H illustrates data for Cy7-PF₆. FIG. 17I illustrates data for Cy7-TRIS. FIG. 17J illustrates data for Cy7-PhB. FIG. 17K illustrates data for Cy7-FPhB. FIG. 17L illustrates data for Cy7-TPFB.

FIG. 18A-18B are images taken 10 seconds apart of the same water contact angle measurement of Cy7-TRIS. The measurement records the contact angle of a water droplet on a neat layer of the Cy7 salt. The tetrabutylammonium presence in the film led to dramatically different water contact angles depending on the time of measurement.

FIG. 19A is a schematic showing representative Cy7 that simulated in Materials Studio with a carboxylic acid-terminated chain. Each anion was simulated with the cation with 5 potential initial positions prior to geometric optimization. FIG. 19B is a graph illustrating minimum binding energy from any of the anion positions plotted against lifetime. Anions with similar structures are used to generate fit lines. The phenyl borate anions re used to predict the lifetime of Cy7 coordinated with tetrakis[3,5-bis(trifluoromethyl)phenyl]borate (TFM, open star) and is then compared to the experimentally determined lifetime (closed star), showing good agreement. Additional lifetimes are predicted of anions. FIG. 19C is a schematic of structures of TFM and the additional anions with lifetimes estimated in FIG. 19B.

FIG. 20 is a graph illustrating 1-T of Cy7-TFM in comparison to Cy7-TPFB and Cy7-BF₄.

FIG. 21 is a graph illustrating water contact angle vs binding energy of each salt.

FIG. 22 is a graph illustrating 1-T of different Cy7 salt with counterion exchange demonstrating a dramatic difference.

FIGS. 23A-23E are chemical structures of various counterions according to various aspects of the present disclosure.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges. As referred to herein, ranges are, unless specified otherwise, inclusive of endpoints and include disclosure of all distinct values and further divided ranges within the entire range. Thus, for example, a range of “from A to B” or “from about A to about B” is inclusive of A and B.

Example embodiments will now be described more fully with reference to the accompanying drawings.

The current technology relates to organic chemistry, organic semiconductors, organic photovoltaics, and organic luminescent solar concentrators (LSCs). The photovoltaic devices and light harvesting systems can be opaque, transparent, heterojunction cells, or multi-junction cells. The devices and systems include at least one of neutral organic molecules, organic salts, and/or luminophores that selectively or predominately harvest light with wavelengths in the infrared (IR) region of the solar spectrum, near IR (NIR) region of the solar spectrum, or both the IR and NIR regions of the solar spectrum.

More particularly, the current technology provides a molecular design strategy for improving the stability of near-infrared absorbers for long-lifetime organic and transparent photovoltaics and transparent luminescent solar concentrators (TLSCs). Tailoring or tuning an absorber and/or a luminophore to maximize thin-film hydrophobicity, minimize absolute magnitude of binding energy, and/or maximize halogenation in available hydrogen sites can yield significant improvements in device lifetime. For organic salts, hydrophobicity is determined largely by a counterion (e.g., a non-photoactive anion or cation) or a photoactive ion (i.e., a photoactive cation or anion), which can enhance device lifetimes by several orders of magnitude with decoupled dependence on orbital energy levels or optical absorption. As used herein, the term “lifetime” refers to the time over which a power conversion efficiency (PCE) of a device reaches either 80% or 50% of an initial value for the device after any burn-in (T₈₀ or T₅₀, respectively).

A solar panel (e.g., a PV or LSC) includes a photoactive material (used interchangeably with “photoactive component”). The photoactive material may be present in an active layer of a PV and/or in a waveguide of an LSC. In certain aspects, the photoactive material may be organic. As used herein, “organic” means that at least one component of the photoactive material (e.g., an ion or a counterion) is organic.

In various aspects, the photoactive material may have a desired (or alternatively, predetermined) water contact angle, absolute value of binding energy, and/or degree of halogenation of available hydrogen sites. In certain aspects, the organic photoactive material may have water contact angle of greater than or equal to about 65° (e.g., greater than or equal to about 70°, greater than or equal to about 75°, greater than or equal to about 80°, greater than or equal to about 85°, greater than or equal to about 90°, greater than or equal to about 95°, or greater than or equal to about) 100°. In certain aspects, the photoactive material is a salt including an ion and a counterion. An absolute magnitude of a binding energy between the ion and the counterion may be less than or equal to about 6.5 eV (e.g., less than or equal to about 6.25 eV, less than or equal to about 6 eV, less than or equal to about 5.75 eV, less than or equal to about 5.5 eV, less than or equal to about 5.25 eV, less than or equal to about 5 eV, less than or equal to about 4.75 eV, less than or equal to about 4.5 eV, less than or equal to about 4.25 eV, less than or equal to about 4 eV, less than or equal to about 3.75 eV, or less than or equal to about 3.5 eV). In certain aspects, the absolute magnitude of the binding energy may be greater than or equal to about 3.25 eV (e.g., greater than or equal to about 3.5 eV, greater than or equal to about 3.75 eV, greater than or equal to about 4 eV, greater than or equal to about 4.25 eV, greater than or equal to about 4.5 eV, greater than or equal to about 4.75 eV, greater than or equal to about 5 eV, greater than or equal to about 5.25 eV, greater than or equal to about 5.5 eV, greater than or equal to about 5.75 eV, greater than or equal to about 6 eV, or greater than or equal to about 6.25 eV). In certain aspects, greater than or equal to about 40% of available hydrogen sites on the counterion are halogenated (i.e., greater than or equal to about 50%, greater than or equal to about 60%, greater than or equal to about 70%, greater than or equal to about 80%, or greater than or equal to about 90%). In at least one example embodiment, a majority of available hydrogen sites are halogenated. In at least one example embodiment, all available hydrogen sites are halogenated.

An photovoltaic device (e.g., including a PV or LSC having the photoactive material as described above) according to certain aspects of the present disclosure may have a lifetime (T₈₀ or T₅₀) of greater than or equal to about 340 hours, greater than or equal to about 500 hours, greater than or equal to about 1,000 hours, greater than or equal to about 2,000 hours, greater than or equal to about 3 months, greater than or equal to about 6 months, greater than or equal to about 5,000 hours, greater than or equal to about 9 months greater than or equal to about 1 year, greater than or equal to about 2 years, greater than or equal to about 3 years, greater than or equal to about 4 years, greater than or equal to about 5 years, greater than or equal to about 6 years, greater than or equal to about 7 years, greater than or equal to about 8 years, greater than or equal to about 9 years, greater than or equal to about 10 years, greater than or equal to about 15 years, greater than or equal to about 20 years, greater than or equal to about 25 years, greater than or equal to about 30 years, or greater than or equal to about 50 years. Accordingly, the lifetime (T₈₀ or T₅₀) can be from greater than or equal to about 340 hours to about 50 years or more.

In at least one example embodiment, a solar panel (i.e., a PV or LSC) according to certain aspects of the present disclosure may be transparent or semi-transparent. The terms “transparent” or “visibly transparent” commonly refer to solar panels that have an average visible transmittance (AVT) of greater than or equal to about 45% (e.g., greater than or equal to about 50%, greater than or equal to about 60%, greater than or equal to about 75%, greater than or equal to about 80%, or greater than or equal to about 90%). The terms “opaque” or “visibly opaque” commonly refer to devices that have an average visible transparency, weighted by the photopic response of an eye of 10% or less for specular transmission. Devices that have an AVT, weighted by the photopic response of an eye, of between 10%-50% are commonly referred to as being “semitransparent.”

As used herein, “substantially absorbent” means that the light absorbing material (e.g., the solar panel) absorbs greater than or equal to about 50% of light of a particular wavelength (e.g., greater than or equal to about 60%, greater than or equal to about 70%, greater than or equal to about 80%, or greater than or equal to about 90% of the light having the particular wavelength). In certain aspects, the solar panel may be substantially absorbent to light having a wavelength of greater than or equal to about 700 nm, greater than or equal to about 710 nm, greater than or equal to about 720 nm, greater than or equal to about 730 nm, greater than or equal to about 740 nm, greater than or equal to about 750 nm, greater than or equal to about 760 nm, greater than or equal to about 770 nm, greater than or equal to about 780 nm, greater than or equal to about 790 nm, greater than or equal to about 800 nm, greater than or equal to about 810 nm, greater than or equal to about 820 nm, greater than or equal to about 830 nm, greater than or equal to about 840 nm, greater than or equal to about 850 nm, greater than or equal to about 860 nm, greater than or equal to about 870 nm, greater than or equal to about 880 nm, greater than or equal to about 890 nm, or greater than or equal to about 900 nm. The solar panel may be substantially absorbent to light having a wavelength of less than or equal to about 380 nm, less than or equal to about 370 nm, less than or equal to about 360 nm, or less than or equal to about 350 nm, less than or equal to about 340 nm, less than or equal to about 330 nm, less than or equal to about 320 nm, less than or equal to about 310 nm, less than or equal to about 300 nm, less than or equal to about 290 nm, or less than or equal to about 280 nm.

In certain aspects, the solar panel may have a largest peak absorption (also referred to as a “primary absorption peak”) that is greater than any absorption peak in visible spectrum. The largest peak absorption may occur at a wavelength of greater than or equal to about 700 nm (e.g., greater than or equal to about 710 nm, greater than or equal to about 720 nm, greater than or equal to about 730 nm, greater than or equal to about 740 nm, greater than or equal to about 750 nm, greater than or equal to about 760 nm, greater than or equal to about 770 nm greater than or equal to about 760 nm, greater than or equal to about 780 nm, greater than or equal to about 790 nm, greater than or equal to about 800 nm, greater than or equal to about 810 nm, greater than or equal to about 820 nm, greater than or equal to about 830 nm, greater than or equal to about 840 nm, greater than or equal to about 850 nm, greater than or equal to about 860 nm, greater than or equal to about 870 nm, greater than or equal to about 880 nm, greater than or equal to about 890 nm, or greater than or equal to about 900 nm). The largest peak absorption may occur at a wavelength of less than or equal to about 1200 nm (e.g., less than or equal to about 1100 nm, less than or equal to about 1050 nm, less than or equal to about 1000 nm, or less than or equal to about 950 nm).

In at least one other example embodiment, the solar panel may have a largest peak absorption at a wavelength of less than or equal to about 380 nm (e.g., less than or equal to about 370 nm, less than or equal to about 360 nm, or less than or equal to about 350 nm, less than or equal to about 340 nm, less than or equal to about 330 nm, less than or equal to about 320 nm, less than or equal to about 310 nm, less than or equal to about 300 nm, less than or equal to about 290 nm, or less than or equal to about 280 nm). The largest peak absorption may occur at a wavelength of greater than or equal to about 200 nm (e.g., greater than or equal to about 250 nm, greater than or equal to about 300 nm, greater than or equal to about 350 nm).

In certain aspects, the solar panel may have a second largest peak absorption (also referred to as a “secondary absorption peak”). The secondary absorption peak may occur at a wavelength of greater than or equal to about 700 nm (e.g., greater than or equal to about 710 nm, greater than or equal to about 720 nm, greater than or equal to about 730 nm, greater than or equal to about 740 nm, greater than or equal to about 750 nm, greater than or equal to about 760 nm, greater than or equal to about 770 nm greater than or equal to about 760 nm, greater than or equal to about 780 nm, greater than or equal to about 790 nm, greater than or equal to about 800 nm, greater than or equal to about 810 nm, greater than or equal to about 820 nm, greater than or equal to about 830 nm, greater than or equal to about 840 nm, greater than or equal to about 850 nm, greater than or equal to about 860 nm, greater than or equal to about 870 nm, greater than or equal to about 880 nm, greater than or equal to about 890 nm, or greater than or equal to about 900 nm). The secondary absorption peak may occur at a wavelength of less than or equal to about 1200 nm (e.g., less than or equal to about 1100 nm, less than or equal to about 1050 nm, less than or equal to about 1000 nm, or less than or equal to about 950 nm).

In at least one other example embodiment, the solar panel may have a secondary absorption peak at a wavelength of less than or equal to about 380 nm (e.g., less than or equal to about 370 nm, less than or equal to about 360 nm, or less than or equal to about 350 nm, less than or equal to about 340 nm, less than or equal to about 330 nm, less than or equal to about 320 nm, less than or equal to about 310 nm, less than or equal to about 300 nm, less than or equal to about 290 nm, or less than or equal to about 280 nm). The secondary absorption peak may occur at a wavelength of greater than or equal to about 200 nm (e.g., greater than or equal to about 250 nm, greater than or equal to about 300 nm, greater than or equal to about 350 nm, or greater than or equal to about 400 nm).

In at least one example embodiment, the transparent solar panel may have an transmission cutoff (also referred to as an “absorption cutoff” or a “wavelength cutoff”) which is a 1-transmission (or absorption) of approximately 5%, 10%, or 15%, or 20% of the peak 1-transmission (or absorption). The transmission cutoff can be at a wavelength of greater than or equal to about 700 nm, greater than or equal to about 710 nm, greater than or equal to about 720 nm, greater than or equal to about 730 nm, greater than or equal to about 740 nm, greater than or equal to about 750 nm, greater than or equal to about 760 nm, greater than or equal to about 770 nm greater than or equal to about 760 nm, greater than or equal to about 780 nm, greater than or equal to about 790 nm, greater than or equal to about 800 nm, greater than or equal to about 810 nm, greater than or equal to about 820 nm, greater than or equal to about 830 nm, greater than or equal to about 840 nm, greater than or equal to about 850 nm, greater than or equal to about 860 nm, greater than or equal to about 870 nm, greater than or equal to about 880 nm, greater than or equal to about 890 nm, or greater than or equal to about 900 nm. In at least one example embodiment, the transparent solar panel may have a transmission cutoff of less than or equal to about 380 nm (e.g., less than or equal to about 370 nm, less than or equal to about 360 nm, or less than or equal to about 350 nm, less than or equal to about 340 nm, less than or equal to about 330 nm, less than or equal to about 320 nm, less than or equal to about 310 nm, less than or equal to about 300 nm, less than or equal to about 290 nm, or less than or equal to about 280 nm).

As used herein, “transmission haze” means the diffuse transmittance (i.e., the amount of light that gets scattered in a device, but that still transmits through) divided by the total transmittance (i.e., the total amount of light that gets trough, whether scattered or not). The solar panel may have a transmission haze of less than or equal to about 100% (e.g., less than or equal to about 90%, less than or equal to about 80%, less than or equal to about 70%, less than or equal to about 60%, less than or equal to about 50%, less than or equal to about 40%, less than or equal to about 30%, less than or equal to about 20%, less than or equal to about 10%, less than or equal to about 5%, less than or equal to about 2%, or less than or equal to about 1%), including a haze of about 20%, about 18%, about 16%, about 14%, about 12%, about 10%, about 8%, about 6%, about 4%, about 2%, about 1%, and less. The solar panel may be substantially free of haze. As used herein, the term “substantially free of haze” means that a device has less than or equal to about 20% haze. The panels may have or be substantially free of visible or average visible haze.

As used herein, the color rendering index (CRI) is the range of perceptible visible light. The CRI is subsequently utilized to determine aesthetic limits for visibly transparent solar cells. Specifically, the CRI is a quantitative metric for evaluating the quality of lighting systems and can be utilized to evaluate the level or perceptible color-tinting of a window. CRIs are calculated based on ideal transmission profiles (step-functions) in combination with International Commission on Illumination (CIE) 1976 three-dimensional uniform color space (CIELUV), CIE 1974 test-color samples, and with correction for chromatic adaptation (non-planckian-locus), when necessary, according to:

$$CRI = \frac{1}{8} {\sum }_{i = 1}^{8} ( 100 - 4.6 \sqrt{{( Δ {L}_{i}^{*} )}^{2} + {( Δ {u}_{i}^{*} )}^{2} + {( Δ {v}_{i}^{*} )}^{2}} ) , \qquad ( 1 )$$

where ΔLᵢ*, Δuᵢ*, and Δvᵢ,* are the difference in lightness (L*) and chromaticity coordinates (u*, v*) between each color sample, i (8 in total) “illuminated” with a fixed reference solar spectrum (AM1.5G) and the transmission sources (T(λ)·AM1.5(λ)). CRI and AVT are described in detail in Lunt, “Theoretical Limits for Visibly Transparent Photovoltaics.” Appl. Phys. Lett., 101, 043902 (2012), which is incorporated herein by reference in its entirety.

In at least one example embodiment, the solar panel may have a CRI of greater than or equal to about 80 (e.g., greater than or equal to about 85, greater than or equal to about 90, or greater than or equal to about 95), referenced to an air mass 1.5 global (AM 1.5 G) solar spectrum. Therefore, in at least one example embodiment, the solar cell is visibly transparent, such that when an observer looks through the solar cell, objects on an opposing side of solar cell appear substantially (or completely) in their natural “color” and substantially without tint or haze. Commission on Illumination (CIE) light utilization efficiency (LUE) color metrics can also be utilized as a substitute for CRI.

Power conversion efficiency (PCE) is derived from current-density (J)—voltage (V) curves, and specifically the electrical power generated divided by the incident solar power. In at least one example embodiment, the solar panel has a PCE of greater than or equal to about 0.3% (e.g., greater than or equal to about 0.5%, greater than or equal to about 0.6%, greater than or equal to about 0.65%, greater than or equal to about 0.7%, greater than or equal to about 0.75%, greater than or equal to about 0.8%, greater than or equal to about 0.9%, greater than or equal to about 1%, greater than or equal to about 1.5%, greater than or equal to about 2.0%, greater than or equal to about 3%, greater than or equal to about 4%, greater than or equal to about 5%, greater than or equal to about 6%, or greater than or equal to about 7%, greater than or equal to about 8%, greater than or equal to about 9%, or greater than or equal to about 10%).

In at least one example embodiment, a surface area of a single solar panel may be greater than or equal to about 0.01 m² (e.g., greater than or equal to about 0.05 m², greater than or equal to about 0.1 m², greater than or equal to about 0.5 m², greater than or equal to about 1 m², greater than or equal to about 1.5 m², or greater than or equal to about 5 m²). The solar cell area may be less than or equal to about 10 m² (e.g., less than or equal to about 5 m², less than or equal to about 2 m², less than or equal to about 1 m², less than or equal to about 0.5 m², less than or equal to about 0.1 m², or less than or equal to about 0.05 m²).

As used herein, external quantum efficiency (EQE) is the efficiency of converting photons of a particular wavelength to electrons. In certain aspects, the EQE may be greater than or equal to about 1% (e.g., greater than or equal to about 1.5%, greater than or equal to about 2%, greater than or equal to about 2.5%, greater than or equal to about 3%, greater than or equal to about 3.5%, greater than or equal to about 4%, greater than or equal to about 4.5%, greater than or equal to about 5%, greater than or equal to about 6%, greater than or equal to about 7%, greater than or equal to about 10%, greater than or equal to about 20%, greater than or equal to about 30%, greater than or equal to about 40%, greater than or equal to about 50%, greater than or equal to about 60%, greater than or equal to about 70%, greater than or equal to about 80%, or greater than or equal to about 90%). The EQE may be less than or equal to about 95%.

Internal quantum efficiency (IQE) is the efficiency of converting absorbed photons of a particular wavelength to electrons. In the absence of reabsorption losses (large concentrator size), the photoluminescence quantum yield (PLQY) can be estimated by dividing the IQE by the waveguiding efficiency (0.75) and the edge mounted PV EQE at the emission wavelength (typically 0.9-0.95). In certain aspects, the IQE may be greater than or equal to about 20% (e.g., greater than or equal to about 30%, greater than or equal to about 40%, greater than or equal to about 50%, greater than or equal to about 60%, greater than or equal to about 70%, greater than or equal to about 80%, or greater than or equal to about 90%).

LUE or light utilization factor is the product of PCE and the AVT. It is a measure of how well the spectrum is utilized for both light transmission and power generation. The LUE may be greater than or equal to about 0.5 (e.g., greater than or equal to about 0.7, greater than or equal to about 1, greater than or equal to about 1.5, greater than or equal to about 2, greater than or equal to about 3, greater than or equal to about 4, greater than or equal to about 5, greater than or equal to about 6, greater than or equal to about 7, greater than or equal to about 8, greater than or equal to about 9, or greater than or equal to about 10). The LUE may be less than or equal to about 10 (e.g., less than or equal to about 9, less than or equal to about 8, less than or equal to about 7, less than or equal to about 6, less than or equal to about 5, less than or equal to about 4, less than or equal to about 3, less than or equal to about 2, or less than or equal to about 1).

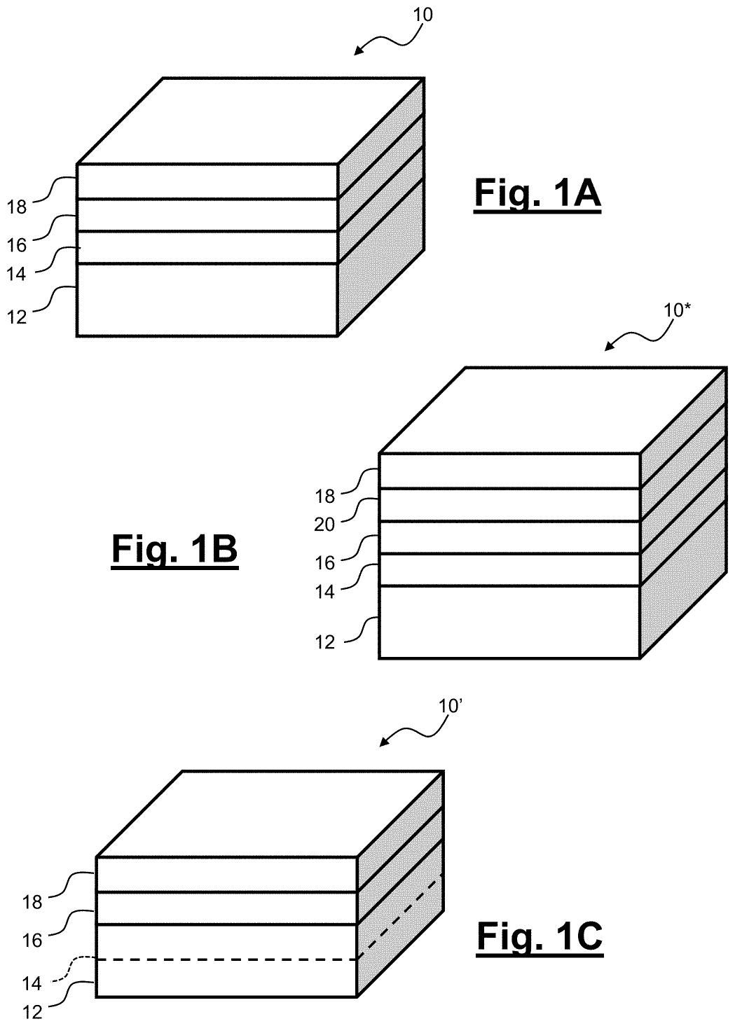

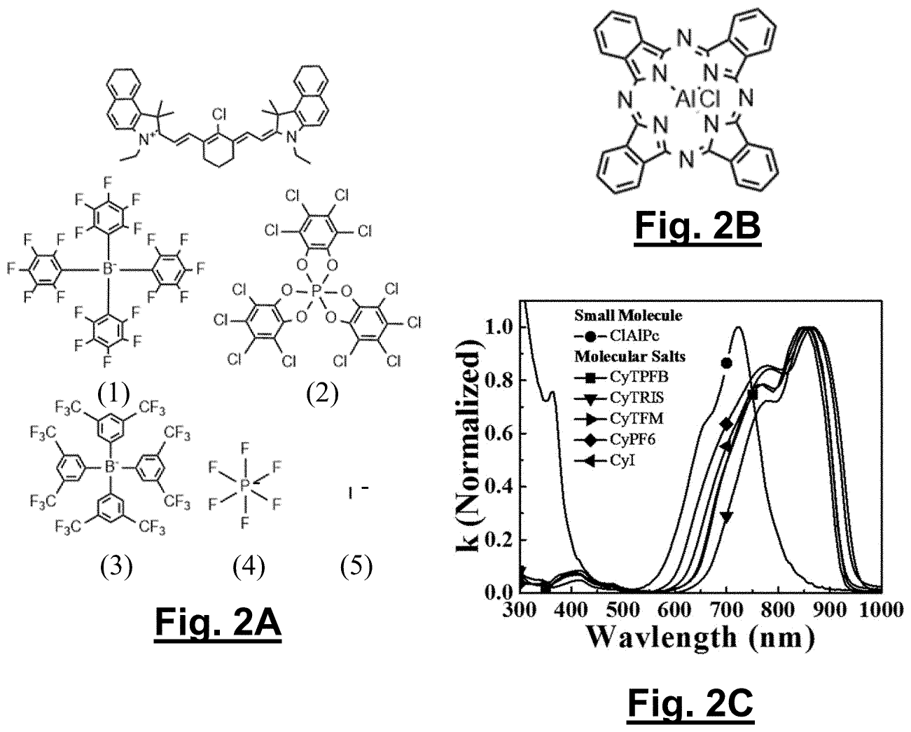

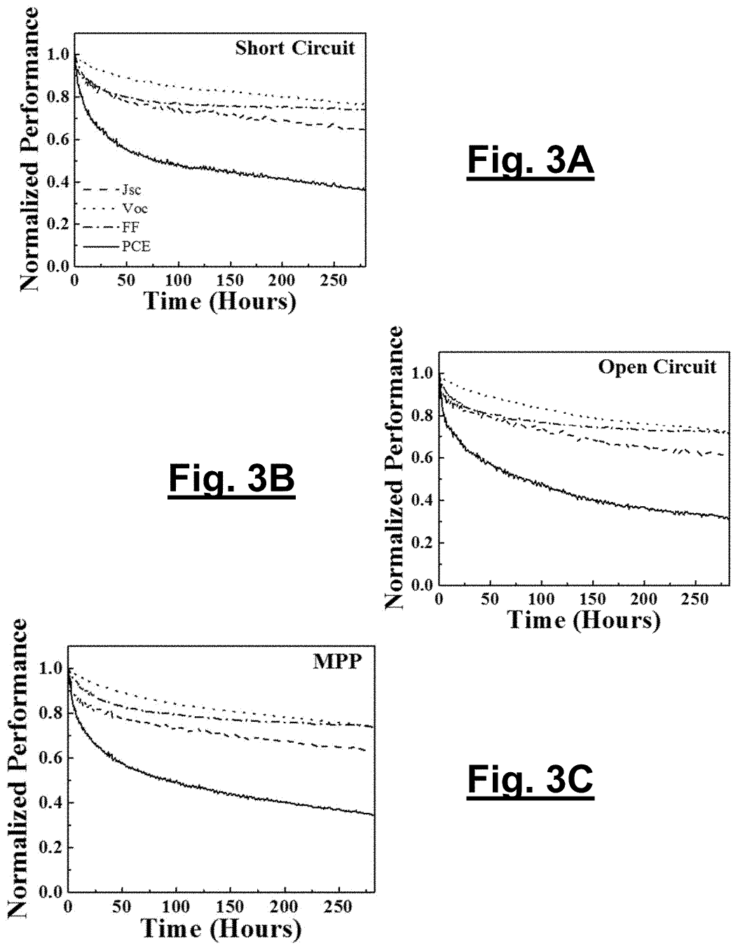

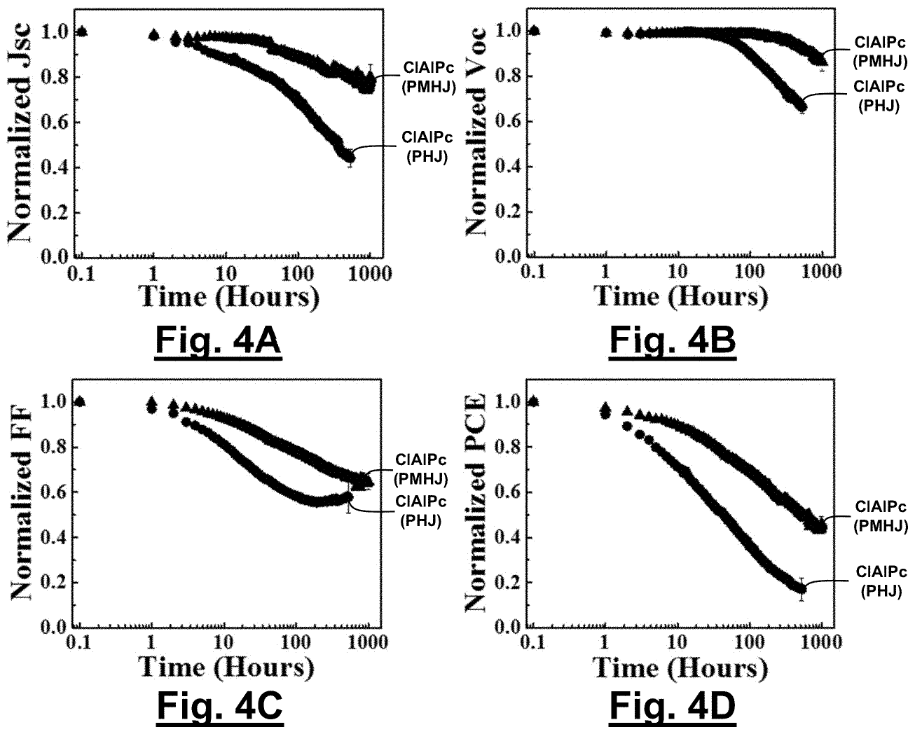

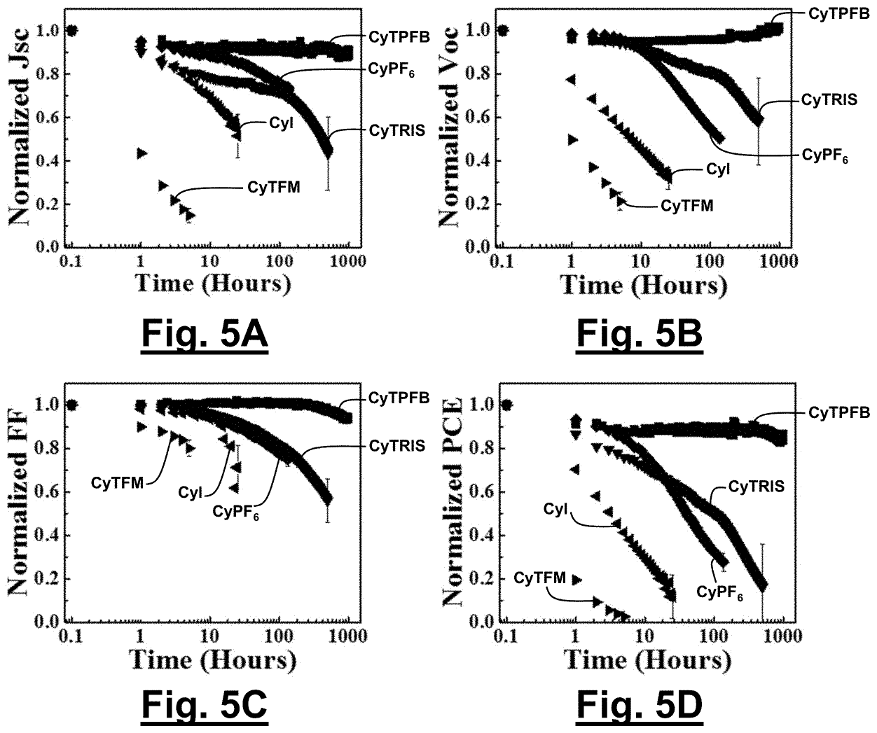

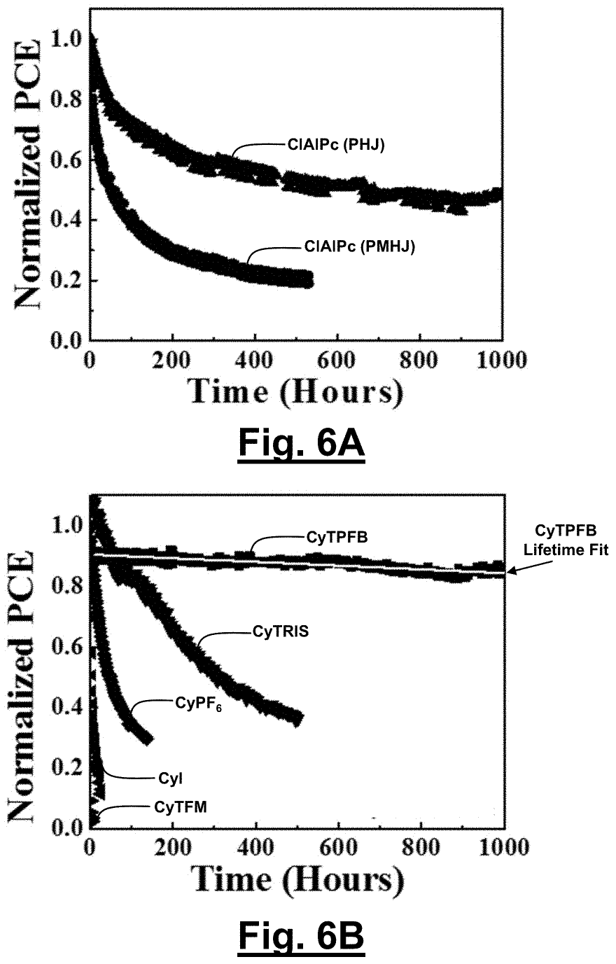

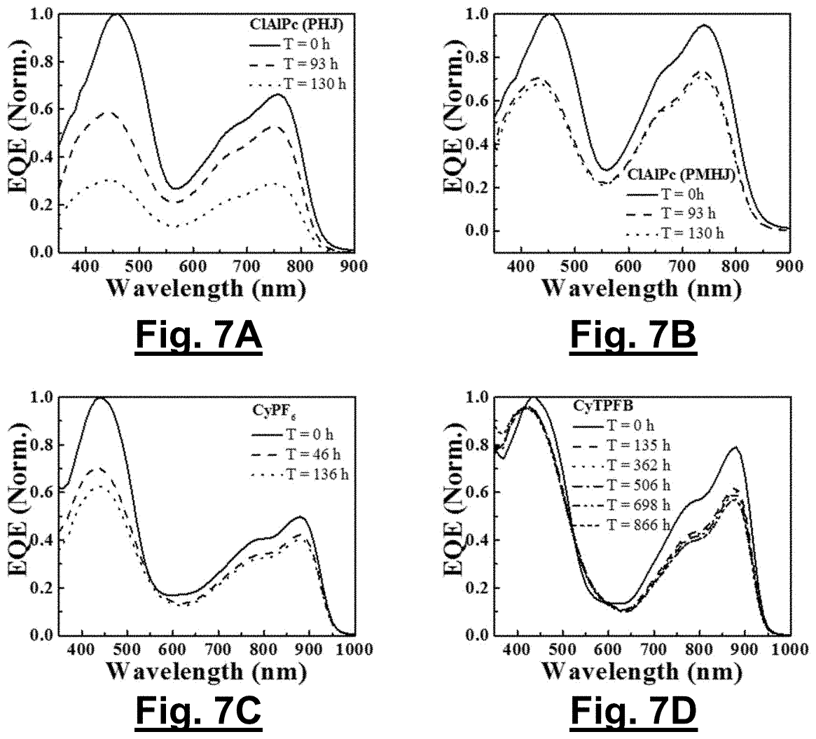

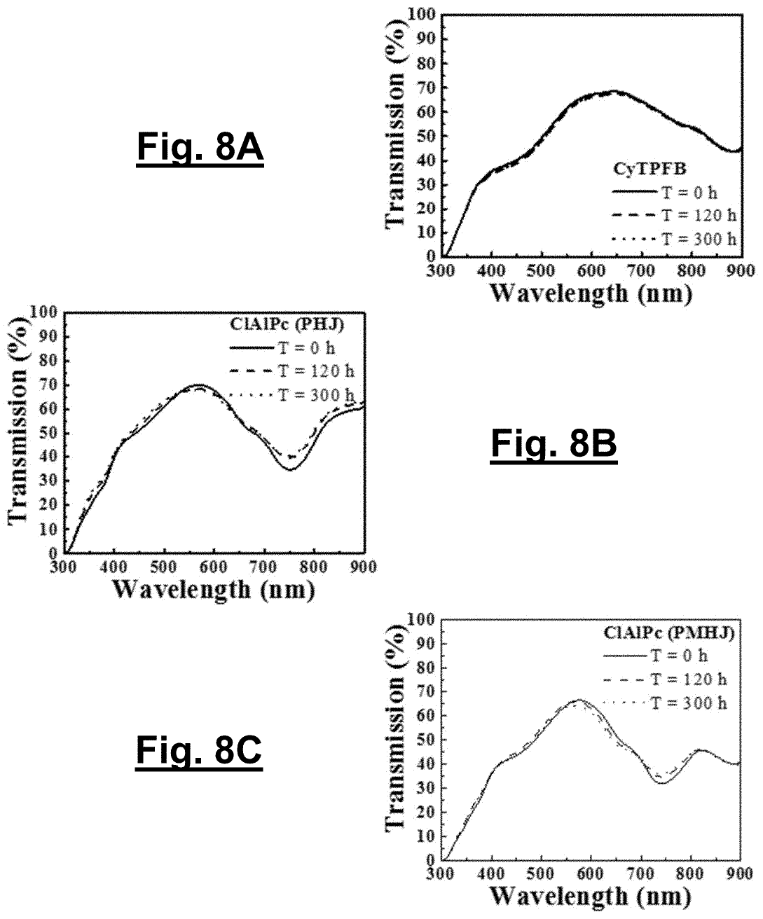

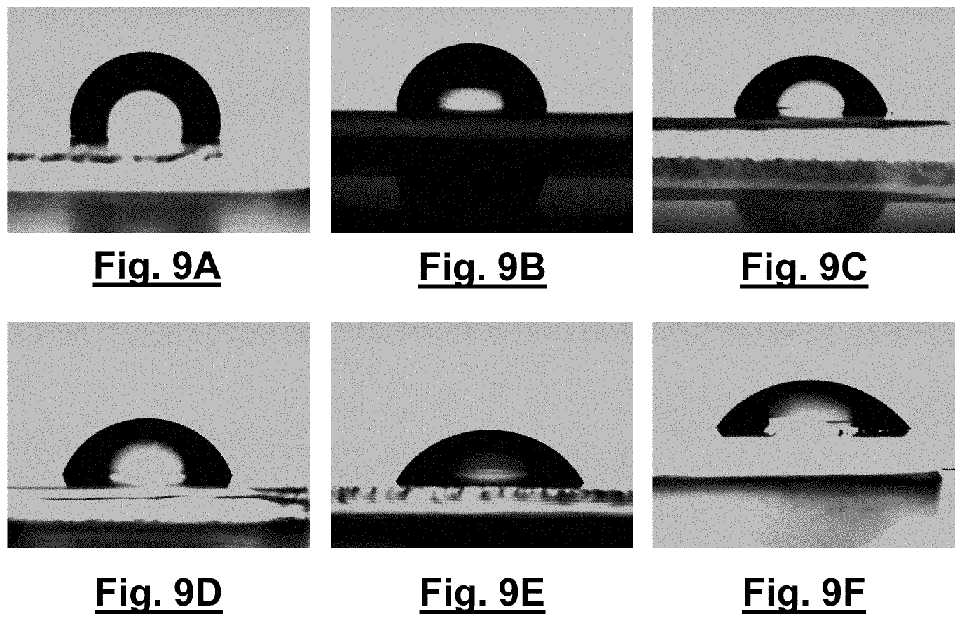

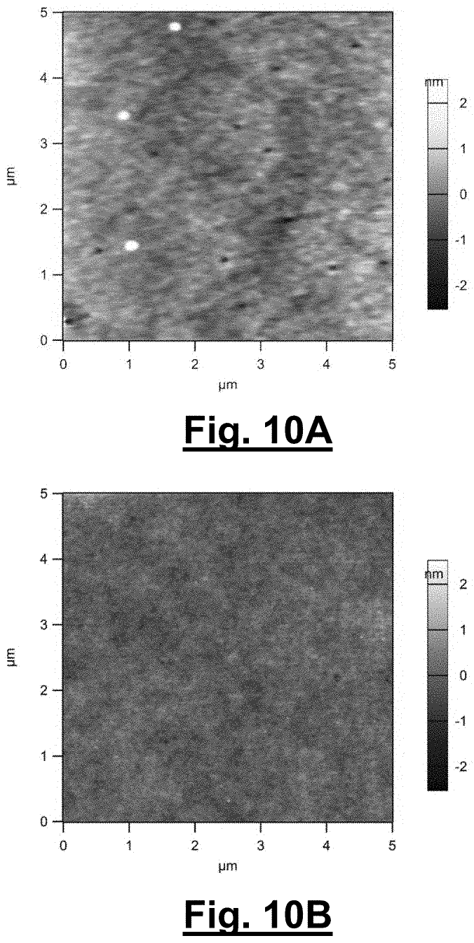

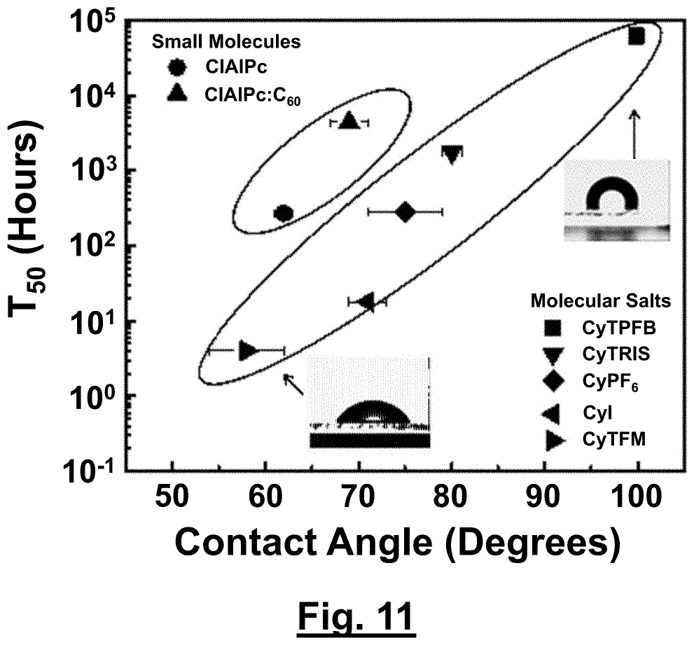

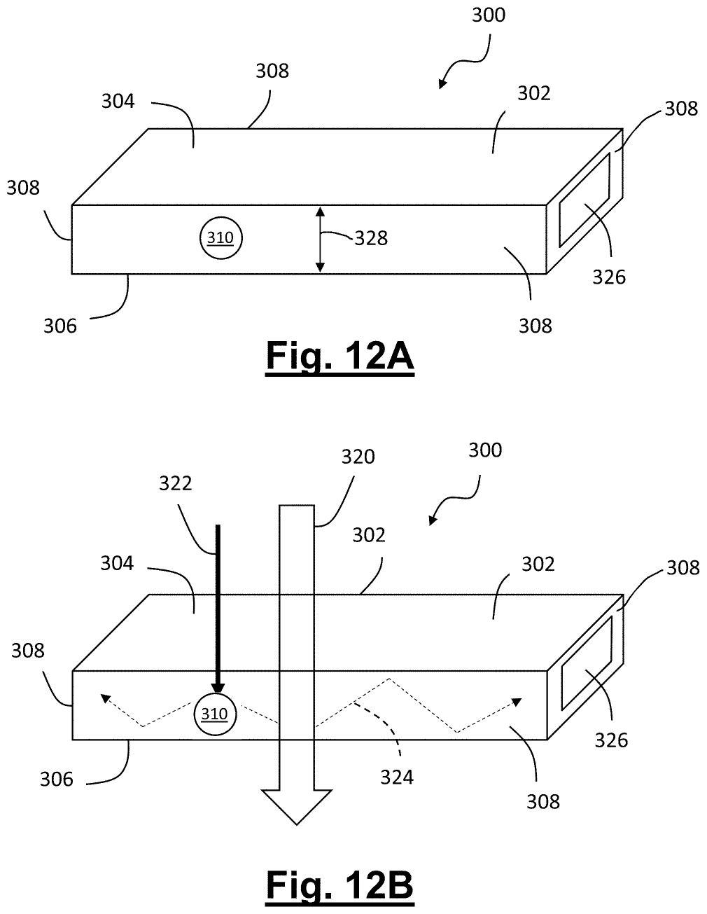

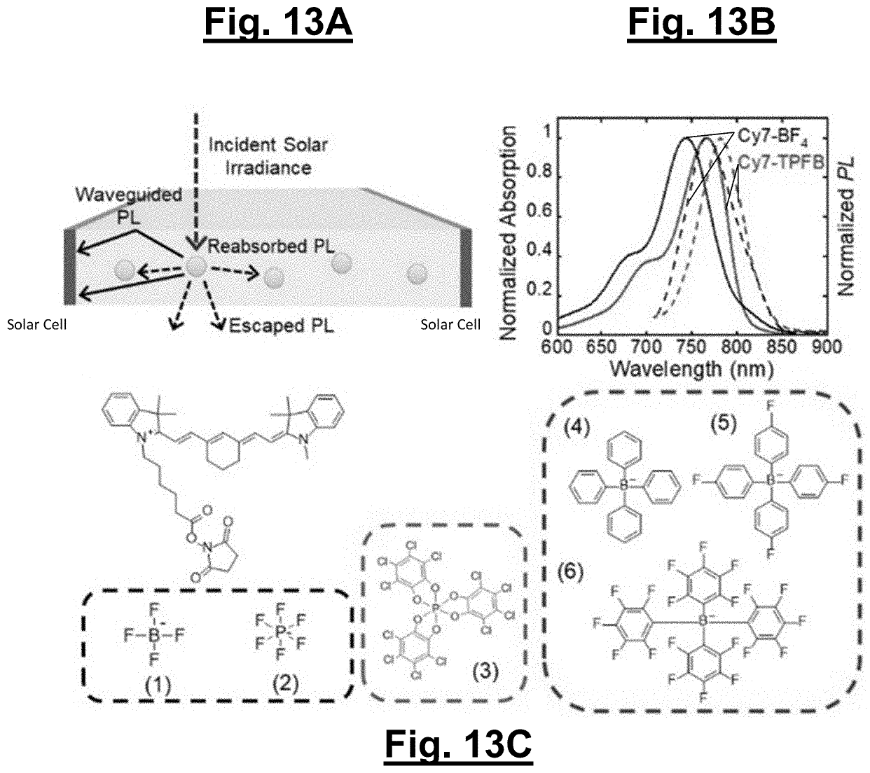

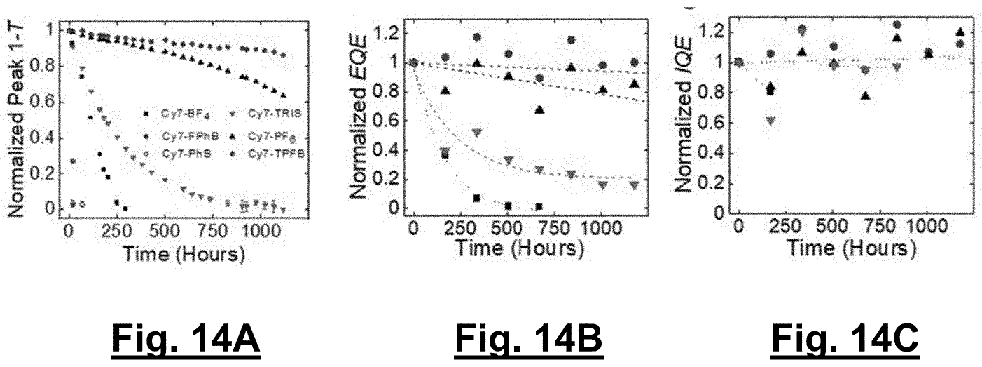

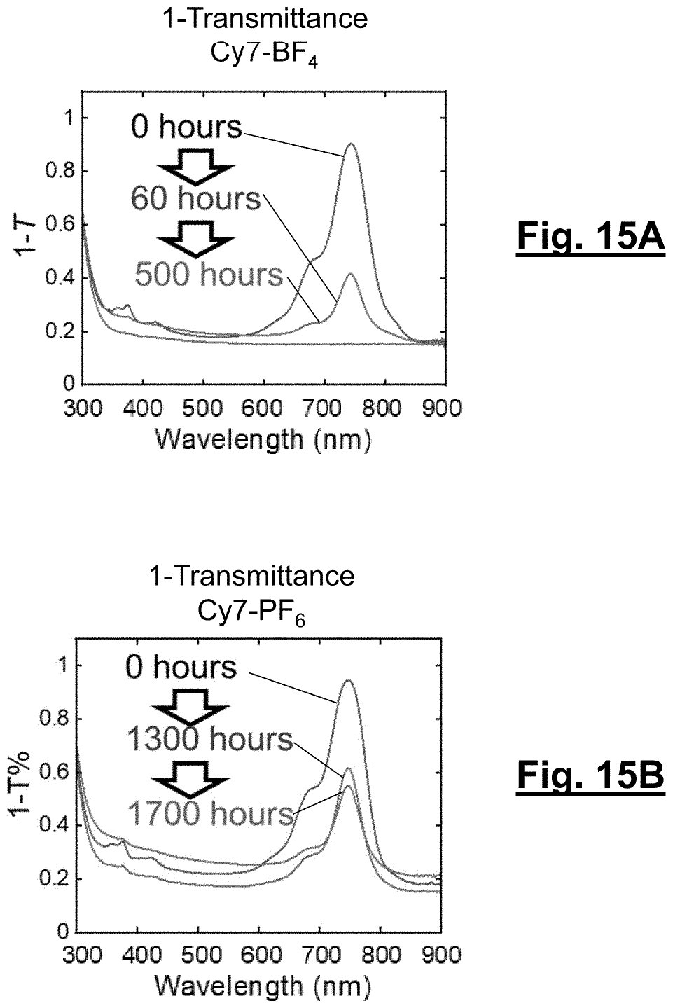

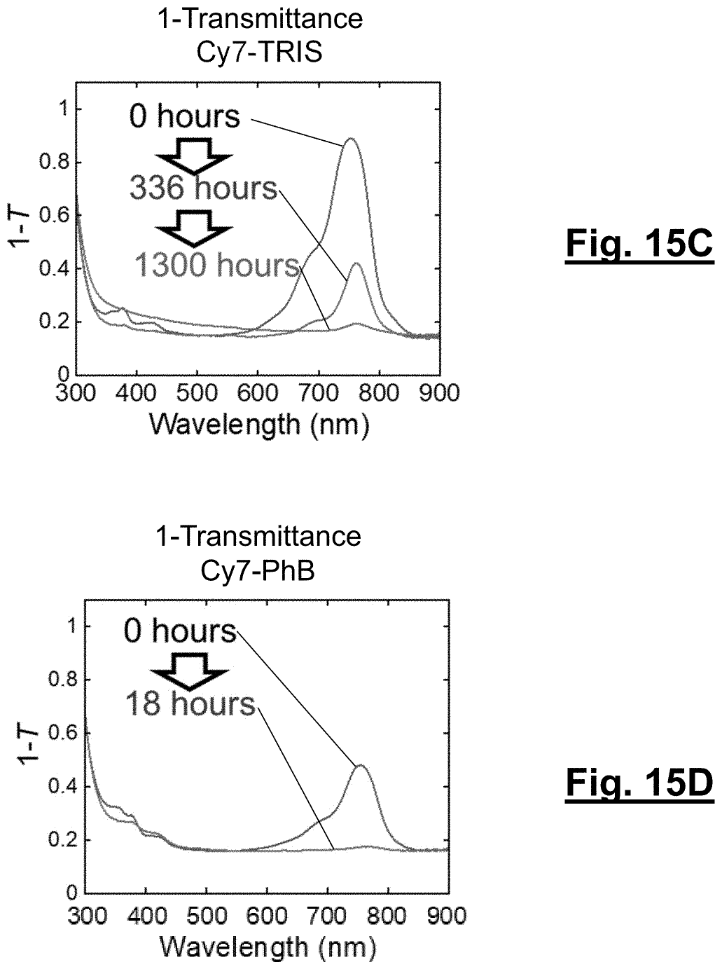

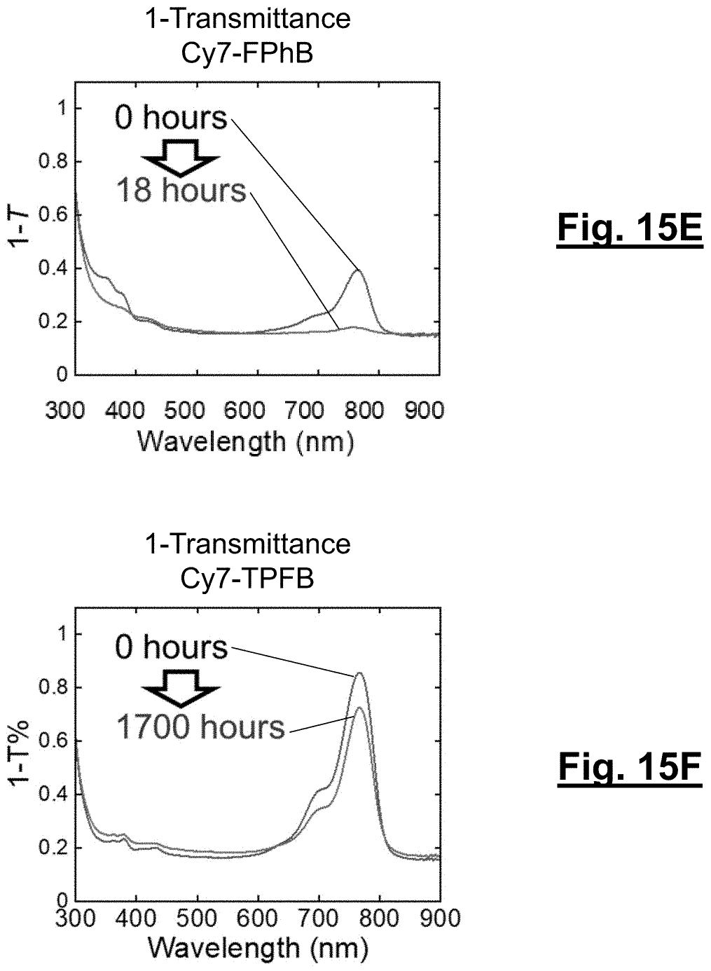

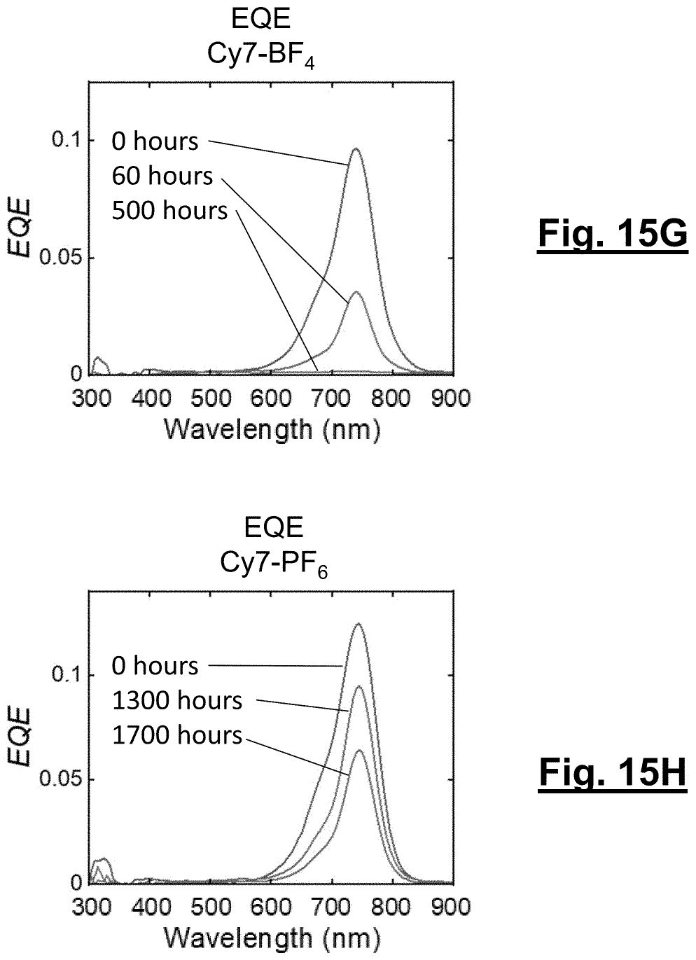

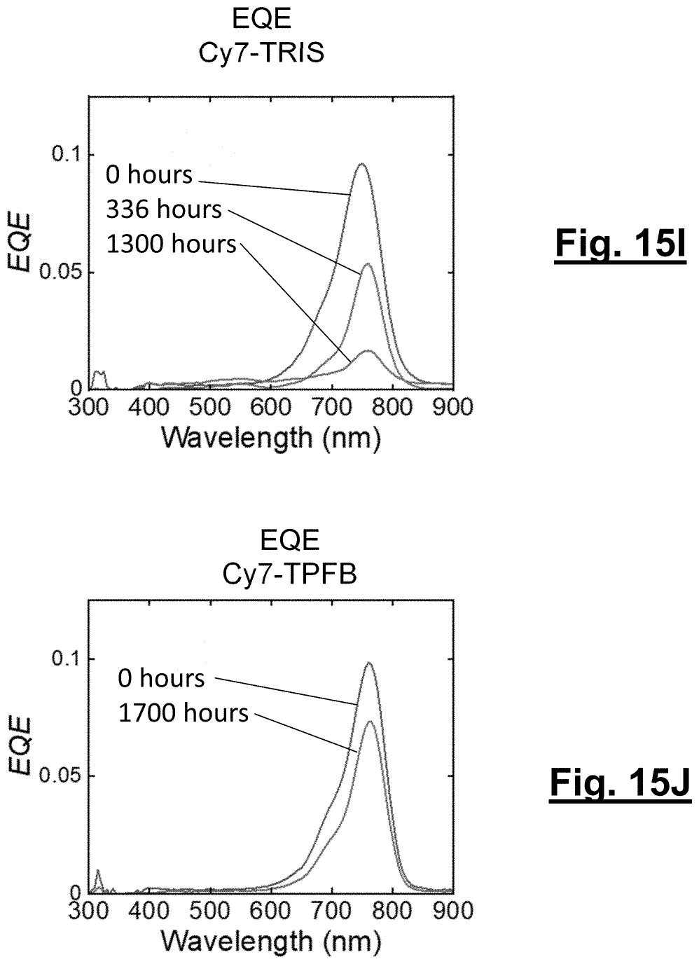

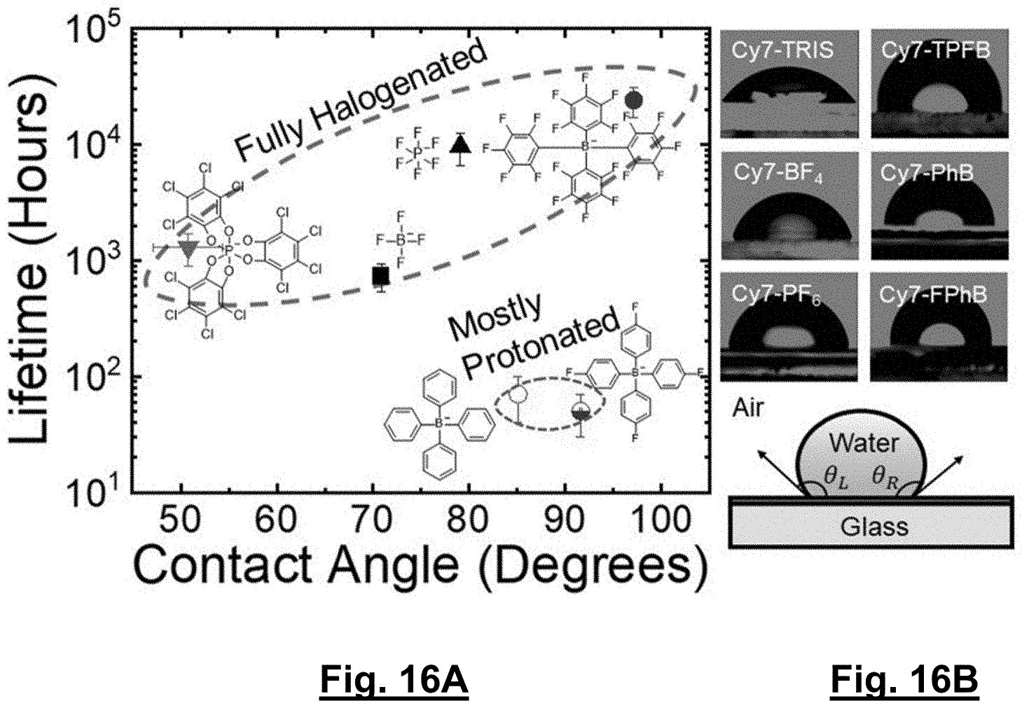

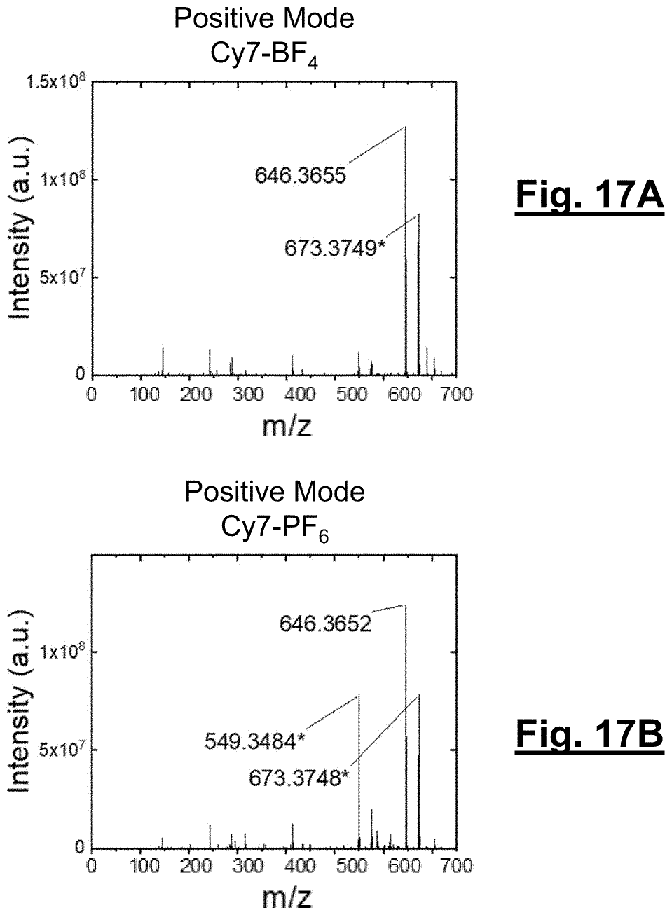

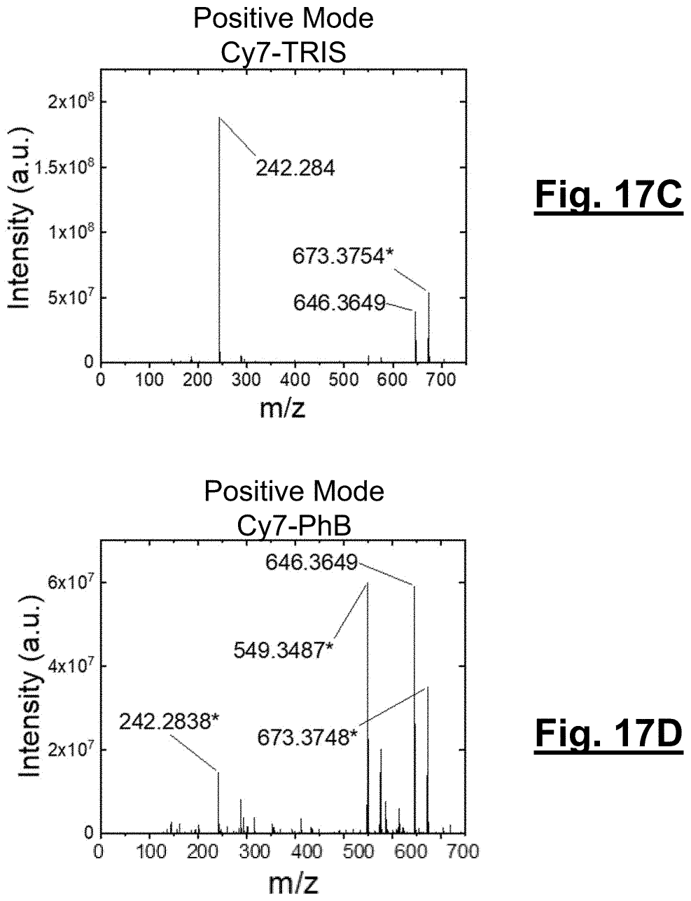

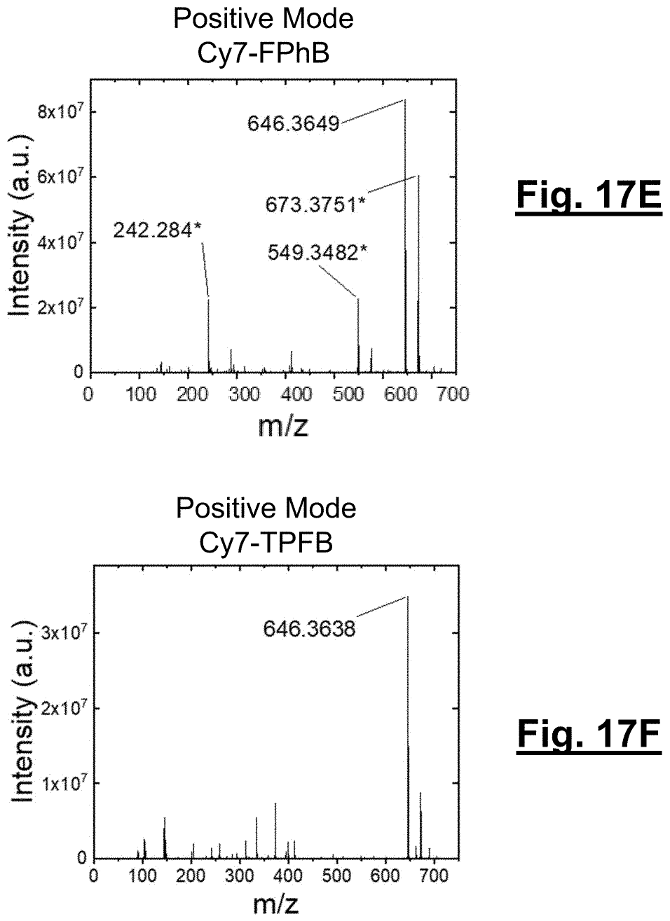

With reference to FIG. 1A, the present technology provides an organic photovoltaic device 10. The photovoltaic device 10 comprises a substrate 12, a first electrode 14, an active layer 16 comprising an organic photoactive component (i.e., an electron donor), and a second electrode 18. In some embodiments, the organic photovoltaic device 10 also includes at least one complementary layer comprising an electron acceptor. The complementary layer can be included in the active layer 16 or provided as a separate distinct complementary layer 20, as shown with another device 10* in FIG. 1B. Therefore, the active layer 16 can comprise, consist essentially of, or consist of the organic photoactive component and the electron acceptor (FIG. 1A), or the active layer 16 can comprise, consist essentially of, or consist of the organic photoactive component and the electron acceptor is provided in a complementary layer 20 (FIG. 1B). Here, the term “consists essentially of” means that a layer can only include trace amounts, i.e., less than or equal to about 10 wt. %, of additional unavoidable impurity materials that do not substantially affect the activity (i.e., by less than about 10%) generated by the pairing of the electron donor (photoactive component) and electron acceptor.

In various embodiments, the photovoltaic device 10, 10* includes at least one, or a plurality of, active layers 16, at least one, or a plurality of, complementary layers 20 that include electron acceptors, or at least one of, or a plurality of, both active layers 16 and complementary layers 20. The active layer 16 and any complementary layers 20 have a thickness of from about 1 nm to about 300 nm, or from about 3 nm to about 100 nm. Although not shown, in some embodiments the photovoltaic device 10, 10* also includes buffer layers positioned between any of the layers and electrodes 12, 14, 16, 18, 20 which may block excitons, modify a work function or collection barrier, induce ordering or templating, or serve as optical spacers. The photovoltaic device 10, 10* has an open circuit voltage that is within about 30% or about 20% of the excitonic limit as defined in Lunt et al., “Practical Roadmap and Limits to Nanostructured Photovoltaics” (Perspective) Adv. Mat. 23, 5712-5727, 2011, which is incorporated herein by reference in its entirety. Briefly, the form for the excitonic limiting open circuit voltage, i.e., the excitonic limit, under 1 Sun follows roughly 80% of the theoretical Shockley-Queisser thermodynamically limited open circuit voltage that is limited by the smallest of the band gaps. The factor of 80% in the excitonic limit accounts for the minimum energetic driving force required to dissociate excitons. Alternatively, the photovoltaic device 10, 10* has an open circuit voltage that is within about 50% or about 35% of the thermodynamic limit.

The substrate 12 of the photovoltaic device 10, 10* can be any visibly transparent or visibly opaque material 12 known in the art. Non-limiting examples of transparent substrates include glass, low iron glass, plastic, poly(methyl methacrylate) (PMMA), poly-(ethyl methacrylate) (FEMA), (poly)-butyl methacrylate-co-methyl methacrylate (PBMMA), polyethylene terephthalate (PET), and polyimides, such as Kapton® polyimide films (DuPont, Wilmington, Del.). Non-limiting examples of opaque substrates include amorphous silicon, crystalline silicon, halide perovskites, stainless steel, metals, metal foils, and gallium arsenide.

The substrate 12 comprises the first electrode 14. As shown in FIGS. 1A and 1B, the first electrode 14 is positioned or deposited on a first surface of the substrate 12 as, for example, a thin film, by solution deposition, drop casting, spin-coating, doctor blading, vacuum deposition, plasma sputtering, or e-beam deposition, as non-limiting examples, with thicknesses that allow for active-layer films that are visibly transparent or visibly opaque. However, in various embodiments, multiple electrodes 14 may be present, such as with a device having a first electrode on a first surface of a substrate and on a second opposing surface of the substrate (not shown). In another embodiment, depicted as FIG. 10, a photovoltaic device 10′ has the same components as the photovoltaic device 10 of FIG. 1A (a substrate 12, an electrode 14, and an active layer 16, and optionally buffer layers); however, the first electrode 14 is positioned within the substrate 12. Therefore, the substrate 12 may include materials that act as the electrode 14, such that the substrate 12 and electrode 14 are visibly indistinguishable. Although not shown, the device 10′ can also include at least one of a complementary layer 20 including an electron acceptor and a buffer layer. In any embodiment, the first electrode 14 can be composed of any material known in the art. Non-limiting examples of electrode materials include indium tin oxide (ITO), aluminum doped zinc oxide (AZO), indium zinc oxide, zinc oxide, and gallium zinc oxide (GZO), ultra-thin metals, such as Ag, Au, and Al, graphene, graphene oxide, poly(3,4-ethylenedioxythiophene) polystyrene sulfonate (PEDOT:PSS), MoO₃, tris-(8-hydroxyquinoline)aluminum (Alq3), and combinations thereof. In various embodiments, the first electrode 14 has a thickness of from about 1 nm to about 500 nm, from about 1 nm to about 200 nm, from about 10 nm to about 200 nm, from about 15 nm to about 150 nm, or from about 500 nm or less. Notwithstanding, it is understood that changing the thickness of the first electrode 14 may alter the visible transparency of the photovoltaic device 10, 10*, 10′ via modulation of complex interference associated with the multiple layers 12, 14, 16 in the photovoltaic device 10, 10*, 10′.

The active layer 16 is positioned or disposed on a surface of the electrode 14 in the photovoltaic device 10, 10*, 10′, such as by solution deposition, drop casting, spin-coating, doctor blading, or vacuum deposition, as non-limiting examples, with thicknesses that allow for films that are visibly transparent or visibly opaque. Therefore, the photovoltaic device 10 includes the first electrode 14, which has a first surface in contact with the substrate 12 and a second surface in direct contact with active layer 16. However, in some embodiments, at least one buffer layer or at least one passive layer is positioned between the substrate 12 and the first electrode 14 and/or at least one buffer layer or at least one passive layer is positioned between the first electrode 14 and the active layer 16. Also, the second electrode 18 may be in direct contact with the active layer 16 or a buffer layer may be positioned between the second electrode 18 and the active layer 16. In some embodiments, such as with the photovoltaic device 10′ of FIG. 10, the first electrode 14 is positioned within the substrate 12. In such embodiments, the active layer 16 is positioned on, and is in direct contact with, a first surface of the substrate 12.

As mentioned above, the active layer 16 comprises a photoactive (electron donor) component, which may be an organic photoactive component. The organic photoactive component is at least one of a neutral organic molecule and an organic salt comprising an ion and a counterion. As understood by a person having ordinary skill in the art when the ion is a cation, the counterion is an anion; and when the ion is an anion, the counterion is a cation. In various embodiments, the photoactive component acts as an electron donor and is paired with electron acceptors in the active layer 16. The electron acceptors are fullerenes, non-fullerenes, or a combination thereof. Non-limiting examples of fullerene electron acceptors include C₂₀ fullerene, C₂₄ fullerene, C₂₆ fullerene, C₂₈ fullerene, C₃₀ fullerene, C₃₂ fullerene, C₃₄ fullerene, C₃₆ fullerene, C₃₈ fullerene, Cao fullerene, C₄₂ fullerene, C₄₄ fullerene, C₄₆ fullerene, C₄₈ fullerene, C₅₀ fullerene, C₅₂ fullerene, C₆C fullerene, C₇C fullerene, C₇₂ fullerene, C₇₄ fullerene, C₇₆ fullerene, C₇₈ fullerene, C₈C fullerene, C₈₂ fullerene, C₈₄ fullerene, C₈₆ fullerene, C₉C fullerene, C₉₂ fullerene, C₉₄ fullerene, C₉₆ fullerene, C₉₈ fullerene, C₁₀₀ fullerene, C₁₈₀ fullerene, C₂₄₀ fullerene, C₂₆₀ fullerene, C₃₂₀ fullerene, C₅₀₀ fullerene, C₅₄₀ fullerene, C₇₂₀ fullerene, [6,6]-phenyl C₆₁ butyric acid methyl ester (PC₆₁BM), bis(1-[3-(methoxycarbonyl) propyl]-1-phenyl)-[6.6]C₆₂ (Bis PC₆₂BM), indene C₆₀ mono adduct (C₆₉-1CMA), indene C₆₉ bis adduct (C₆₀-ICBA), indene C₆₀ tris adduct (C₆₀-ICTA), C₆₀-(N,N-dimethyl pyrrolidinium iodide) adduct (WSC₆₀PI), C₆₀-(N,N-dimethyl pyrrolidinium ammonium)n adduct (WSC₆₀PS), C₆₀-(malonic acid)n (WSC₆₉MA), C₆₉(OH)n with n=30-50 (fullerol C₆₀), [6,6]-phenyl C₇₁ butyric acid methyl ester (PC₇₁BM), bis(1-[3-(methoxycarbonyl) propyl]-1-phenyl)-[6.6]072 (Bis PC₇₂BM), indene C₇₀ mono adduct (C₇₉-ICMA), indene C₇₀ bis adduct (C₇₀-ICBA), indene C₇₀ tris adduct (C₇₀-ICTA), C₇₀-(N,N-dimethyl pyrrolidinium iodide) adduct (WSC₇₉PS), C₇₀-(N,N-dimethyl pyrrolidinium ammonium)n adduct (WSC₇₀PS), C₇₀-(malonic acid)n (WSC₇₀MA), C₇₉(OH)n with n=30-50 (fullerol C₇₀), and combinations thereof. Non-limiting examples of non-fullerene electron acceptors include perylene diimides (PDI)-based non-fullerenes, diketopyrrolopyrrole (DPP)-based non-fullerenes, indacenodithiophene (IDT)-based non-fullerenes, and indacenodithienol[3,2-b]thipene (IDTT)-based non-fullerenes, and combinations thereof. Non-limiting specific examples of non-fullerenes include 3,9-bis(2-methylene-(3-(1,1-dicyanomethylene)-indanone))-5,5,11,11-tetrakis(4-hexylphenyl)-dithieno[2,3-d:2′,3′-d′]-s-indaceno[1,2-b:5,6-b]dithiophene (ITIC), 3,9-bis(2-methylene-(3-(1,1-dicyanomethylene)-5,6-difluoroindanone))-5,5,11,11-tetrakis(4-hexylphenyl)-dithieno[2,3-d:2′,3′-d′]-s-indaceno[1,2-b:5,6-b′]dithiopene (ITIC-4F, fluoro ITIC), IEICO (2055812-53-6), IEICO-4F (CAS No. 2089044-02-8), and combinations thereof.

For opaque (non-transparent) devices 10, the organic photoactive component harvests (absorbs) light having any wavelength, i.e., at least one of UV, VIS, NIR, and IR light. For visibly transparent devices 10, the organic photoactive component harvests (absorbs) light with strongest peak wavelengths in the NIR, or IR regions of the solar spectrum, or both the NIR and IR regions. As used herein, “UV” light has a wavelength of greater than or equal to about 10 nm to less than about 400 nm, “VIS” light has a wavelength of greater than or equal to about 400 nm to less than or equal to about 675 nm, “NIR” light has a wavelength of greater than about 675 nm to less than or equal to about 1500 nm, and “IR” light has a wavelength of greater than about 1500 nm to less than or equal to about 1 mm. In embodiments where the device 10, 10*, 10′ is visibly transparent, the organic photoactive component has a strongest peak absorbance of greater than or equal to about 675 nm, where less than or equal to about 20% or less than or equal to about 10% of the total light contacting the organic photoactive component is absorbed by the organic photoactive component. Put another way, in visibly transparent devices 10, the organic photoactive component absorbs light such that less than or equal to about 20% or less than or equal to about 10% of the total light absorbed by the photoactive component has a wavelength of less than about 675 nm.

In various embodiments, the photoactive neutral organic molecule is a cyanine, phthalocyanine, a porphyrin, a thiophene, a perylene, a polymer, derivatives thereof, and combinations thereof, as non-limiting examples. For example, a phthalocyanine can include copper phthalocyanine, and chloroaluminum phthalocyanine (ClAlPc).

In various embodiments, the photoactive organic salt is a polymethine salt, cyanine salt, derivative thereof, or combination thereof, as non-limiting examples. Non-limiting examples of suitable organic ions (which are “base ions” relative to their derivatives) that form organic salts in the presence of a counterion include 1-Butyl-2-(2-[3-[2-(1-butyl-1H-benzo[cd]indol-2-ylidene)-ethylidene]-2-phenyl-cyclopent-1-enyl]-vinyl)-benzo[cd]indolium (peak absorbance at 1024 nm), 1-Butyl-2-(2-[3-[2-(1-butyl-1H-benzo[cd]indol-2-ylidene)-ethylidene]-2-chloro-cyclohex-1-enyl]-vinyl)-benzo[cd]indolium (peak absorbance at 1014 nm), 1-Butyl-2-(2-[3-[2-(1-butyl-1H-benzo[cd]indol-2-ylidene)-ethylidene]-2-phenyl-cyclohex-1-enyl]-vinyl)-benzo[cd]indolium (peak absorbance at 997 nm), 1-Butyl-2-(2-[3-[2-(1-butyl-1H-benzo[cd]indol-2-ylidene)-ethylidene]-2-diphenylamino-cyclopent-1-enyl]-vinyl)-benzo[cd]indolium (peak absorbance at 996 nm), 1-Butyl-2-[7-(1-butyl-1H-benzo[cd]indol-2-ylidene)-hepta-1,3,5-trienyl]benzo[cd]indolium (peak absorbance at 973 nm), 2-[2-[2-chloro-3-[2-(1,3-dihydro-3,3-dimethyl-1-ethyl-2H-benz[e]indol-2-ylidene)ethylidene]-1-cylohexen-1-yl]ethenyl]-3,3-dimethyl-1-ethyl-1H-benz[e]indolium (“Cy+”; peak absorbance at 820 nm), N,N,N′,N′-Tetrakis-(p-di-n-butylaminophenyl)-p-benzochinon-bis-immonium (peak absorbance at 1065 nm), 4-[2-[2-Chloro-3-[(2,6-diphenyl-4H-thiopyran-4-ylidene)ethylidene]-1-cyclohexen-1-yl]ethenyl]-2,6-diphenylthiopyrylium, 1-Butyl-2-[2-[3-[(1-butyl-6-chlorobenz[cd]indol-2(1H)-ylidene)ethylidene]-2-chloro-5-methyl-1-cyclohexen-1-yl]ethenyl]-6-chlorobenz[cd]indolium, 1-Butyl-2-[2-[3-[(1-butyl-6-chlorobenz[cd]indol-2(1H)-ylidene)ethylidene]-2-chloro-1-cyclohexen-1-yl]ethenyl]-6-chlorobenz[cd]indolium, Dimethyl{4-[1,7,7-tris(4-dimethylaminophenyl)-2,4,6-heptatrienylidene]-2,5-cyclohexadien-1-ylidene}ammonium, 5,5′-Dichloro-11-diphenylamino-3,3′-diethyl-10,12-ethylenethiatricarbocyanine, 2-[2-[2-Chloro-3-[2-(1,3-dihydro-1,1,3-trimethyl-2H-benzo[e]-indol-2-ylidene)-ethylidene]-1-cyclohexen-1-yl]-ethenyl]-1,1,3-trimethyl-1H-benzo[e]indolium, 2-[2-[2-Chloro-3-[2-(1,3-dihydro-1,3,3-trimethyl-2H-indol-2-ylidene)-ethylidene]-1-cyclopenten-1-yl]-ethenyl]-1,3,3-trimethyl-3H-indolium, 2-[2-[3-[(1,3-Dihydro-3,3-dimethyl-1-propyl-2H-indol-2-ylidene)ethylidene]-2-(phenylthio)-1-cyclohexen-1-yl]ethenyl]-3,3-dimethyl-1-propylindolium, 1,1′,3,3,3′,3′-4,4′, 5,5′-di-benzo-2,2′-indotricarbocyanine perchlorate, 2-[2-[2-Chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium, 3,3′-Diethylthiatricarbocyanine, 2-[[2-[2-[4-(dimethylamino)phenyl]ethenyl]-6-methyl-4H-pyran-4-ylidene]methyl]-3-ethyl, 2-[7-(1,3-Dihydro-1,3,3-trimethyl-2H-indol-2-ylidene)-1,3,5-heptatrienyl]-1,3,3-trimethyl-3H-indolium, cyanine3 (Cy3), cyanine3.5 (Cy3.5), cyanine5 (Cy5), cyanine5.5 (Cy5.5), cyanine7 (Cy7), cyanine7.5 (Cy7.5), derivatives thereof, and combinations thereof. As used herein, “derivatives” of the organic ions refer to or include organic ions that resemble a base organic ion, but that contain minor changes, variations, or substitutions, such as in, for example, solubilizing groups with varying alkyl chain length or substitution with other solubilizing groups, which do not substantially change the bandgap or electronic properties, as well as substitutions at a central methane position (X,Y) with various halides or ligands.

Non-limiting examples of counterions (which are “base counterions” relative to their derivatives) that form salts with the organic ions include halides, such as F—, Cl—, I—, and Br—; aryl borates, such as tetraphenylborate, tetra(p-tolyl)borate, tetrakis(4-biphenylyl)borate, tetrakis(1-imidazolyl)borate, tetrakis(2-thienyl)borate, tetrakis(4-chlorophenyl)borate, tetrakis(4-fluorophenyl)borate, tetrakis(4-tert-butylphenyl)borate, tetrakis(pentafluorophenyl)borate (TPFB), tetrakis[3,5-bis(trifluoromethyl)phenyl]borate (TFM), [4-[bis(2,4,6-trimethylphenyl)phosphino]-2,3,5,6-tetrafluorophenyl]hydrobis(2,3,4,5,6-pentafluorophenyl)borate, [4-di-tert-butylphosphino-2,3,5,6-tetrafluorophenyl]hydrobis(2,3,4,5,6-pentafluorophenyl)borate, carboranes, (∧, R)-(1,1′-binaphthalene-2,2′diolato)(bis(tetrachlor-1,2-benzenediolato)phosphate(V)) (BINPHAT), [Δ-tris(tetrachloro-1,2-benzenediolato)phosphate(V)] (TRISPHAT); fluoroantimonates, such as hexafluoroantimonate (SbF₆⁻); fluorophosphates, such as hexafluorophophosphate (PF₆⁻); fluoroborates, such as tetrafluoroborate (BF₄); derivatives thereof; and combinations thereof. As used herein, “derivatives” of the counterion refer to or include counterions or anions that resemble a base counterion, but that contain minor changes, variations, or substitutions, that do not substantially change the ability of the counterion to form a salt with the organic ion. Additionally or alternatively, the active layer 16 may include ions and counterions described below in the discussion of luminophore 310.

The organic photoactive component has a water contact angle of greater than or equal to about 65°, greater than or equal to about 70°, greater than or equal to about 80°, greater than or equal to about 90°, greater than or equal to about 95°, or greater than or equal to about 100°. Put another way, the active layer 16 comprising or consisting essentially of the photoactive component has the above water contact angle. Put yet another way, the active layer 16 comprising or consisting essentially of the photoactive component and the electron acceptor have the above water contact angle. Put yet another way still, the active layer 16 has the above water contact angle. Therefore, in various embodiments, the photoactive neutral organic molecule or the counterion of a photoactive organic salt is modified or tuned to include at least one hydrophobic moiety, which increases the water contact angle. The hydrophobic moiety, for example, can be covalently bonded to the neutral organic molecule or counterion. Non-limiting examples of suitable hydrophobic moieties include —CH₃, —SH, —Cl, —F, —CCl₃, PhCl₆, -PhCl₅, —CF₃, PhF₆, -PhF₅, -PhF_{X}Cl_{y} (X=1 to 5 and Y=5-X), -PhF_{X}H_{y} (X=1 to 5 and Y=5-X), -PhCl_{X}H_{y} (X=1 to 5 and Y=5-X), PhF_{X}Br_{y} (X=1 to 5 and Y=5-X), PhF_{X}I_{y} (X=1 to 5 and Y=5-X), PhCl_{X}Br_{y} (X=1 to 5 and Y=5-X), PhBr_{X}I_{y} (X=1 to 5 and Y=5-X), PhF_{X}Cl_{y}Br_{z} (X=1 to 5, Y=5-X-Z, and Z=5-Y-X), and other fluorocarbons, polar hydrophobic groups, and non-hydrogen-bond-forming groups. Less hydrophobic moieties include —OH, —COOH, (Ph)-CH, CN, —SOO, and combinations thereof. Relatively less hydrophobic moieties that may be utilized under various conditions include —OH, —COOH, (Ph)-CH, and combinations thereof, wherein the —OH, —COOH, and (Ph-CH) are more wettable (hydrophilic) and/or hydrogen bonding prone relative to the remaining moieties. As described further below, organic photoactive components with high water contact angles, i.e., greater than or equal to about 65°, provide device lifetimes of greater than or equal to about 1 year. As known by a person having ordinary skill in the art, a “water contact angle” is an angle where a water-vapor interface meet a solid surface of the active layer 16.

In various embodiments, the photoactive neutral organic molecule and/or the photoactive organic salt has an absolute highest occupied molecular orbital (HOMO) energy of greater than or equal to about 5.0 eV to less than or equal to about 5.6 eV, such as a HOMO energy of about 5.0 eV, about 5.1 eV, about 5.2 eV, about 5.3 eV, about 5.4 eV, about 5.5 eV, or about 5.6 eV. This HOMO energy provides elevated voltages and prevents unintended reactions with reactive oxygen species. The HOMO energy can be tuned by adding functional groups to photoactive neutral organic molecules or to counterions of photoactive organic salts. Tuning can also be performed by blending two or more anions together. Methods of tuning HOMO energies are further described in U.S. patent application Ser. No. 15/791,949 to Lunt et al., filed on Oct. 24, 2017, which is incorporated herein by reference in its entirety.

As shown in FIG. 1A, the second electrode 18 is positioned or deposited on a surface of the active layer 16 as, for example, a thin film. The second electrode 18, is positioned or deposited on the surface of the active layer 16 by solution deposition, drop casting, spin-coating, doctor blading, vacuum deposition, plasma sputtering, or e-beam deposition, as non-limiting examples, with thicknesses that allow for active-layer films that are visibly transparent or visibly opaque. Therefore, the second electrode 18 is in contact with a surface of the active layer 16 that opposes a surface of the active layer that is in contact with the first electrode 14. The second electrode 18 can be composed of any material known in the art. Non-limiting examples of electrode materials include indium tin oxide (ITO), aluminum doped zinc oxide (AZO), zinc oxide, and gallium zinc oxide (GZO), ultra-thin metals, such as Ag, Au, and Al, graphene, graphene oxide, poly(3,4-ethylenedioxythiophene) polystyrene sulfonate (PEDOT:PSS), and combinations thereof. In various embodiments, the second electrode 18 has a thickness of from about 1 nm to about 500 nm, from about 1 nm to about 200 nm, from about 10 nm to about 200 nm, from about 15 nm to about 150 nm, or from about 500 nm or less. Notwithstanding it is understood that changing the thickness of the second electrode 18 may alter the visible transparency of the photovoltaic device via modulation of complex optical interference and absorption associated with the multiple layers 12, 14, 16 in the photovoltaic device 10.

With further regard to the first electrode 14 and the second electrode 18, at least one of the electrodes 14, 18 may be visibly transparent in embodiments where the device is visibly opaque. In embodiments where the device is visibly transparent, both the first electrode 14 and the second electrode 18 are visibly transparent with thicknesses tailored to optimize the visible transparency in the active layer 16.

Although not shown in FIG. 1A or 1B, in various embodiments the photovoltaic devices 10, 10′ further include additional active layers, such as electron donors and/or electron acceptors, passive layers, electrode layers, or combinations thereof. For example, additional active layers may include molybdenum oxide (MoO₃), bathocuproine (BCP), C₆₀, or ITO. Additional electrodes may be composed of layers of Ag, Au, Pt, Al, or Cu. Additional non-limiting examples of electron acceptors include of C₇₀, C₈₄, [6,6]-phenyl-C61-butyric acid methyl ester, TiO₂, metal oxides, perovskites, other organic salts, organic molecules, or polymers. Active layers can be composed of neat planar layers of donor-acceptor pairs, mixed layers of blended donor-acceptor pairs, or graded layers of blended donor-acceptor pairs. In various embodiments, the photovoltaic device 10, 10′ is integrated into a multijunction device architecture as a subcell, wherein the multijunction device is either visibly transparent or visibly opaque. As described above, the photovoltaic device 10, 10′ can be incorporated into a photovoltaic or a photodetector. In various embodiments, the device 10, 10′ is sealed or hermetically sealed to prevent exposure of the substrate 12; electrodes 14, 18; active layer 16; and any additional layers. For example, the device 10, 10′ can be disposed within a sealed or hermetically sealed glass or plastic encapsulation.

As described above, the lifetime of organic photovoltaic devices can be extended by increasing the water contact angle of the organic photoactive component. The water contact angle can be increased by increasing the hydrophobicity of the organic photoactive component. Accordingly, the current technology also provides a method of fabricating an organic photovoltaic device having a lifetime (T₈₀ or T₅₀) of greater than or equal to about 340 hours, greater than or equal to about 1 year, greater than or equal to about 2 years, greater than or equal to about 3 years, greater than or equal to about 4 years, greater than or equal to about 5 years, greater than or equal to about 6 years, greater than or equal to about 7 years, greater than or equal to about 8 years, greater than or equal to about 9 years, greater than or equal to about 10 years, greater than or equal to about 15 years, greater than or equal to about 20 years, greater than or equal to about 25 years, greater than or equal to about 30 years, or greater than or equal to about 50 years. Accordingly, the lifetime (T₈₀ or T₅₀) can be from greater than or equal to about 340 hours to about 50 years or more.

The method comprises selecting an organic photoactive component. The organic photoactive component can be any photoactive neutral molecule or photoactive organic salt described herein. The method also comprises measuring a water contact angle of the organic photoactive component and determining whether the organic photoactive component has an acceptable water contact angle of greater than or equal to about 65° greater than or equal to about 70°, greater than or equal to about 80°, greater than or equal to about 90°, greater than or equal to about 95°, or greater than or equal to about 100°. An acceptable water contact angle can be predetermined. Methods of measuring water contact angles are known in the art and include, for example, the static sessile drop method, the pendent drop method, and the dynamic sessile drop method.

In some embodiments the organic photoactive component has an acceptable water contact angle, for example, a predetermined water contact angle of about 65°. When the water contact angle is not acceptable, i.e., when the water contact angle is less than about 65°, the method comprises tuning the organic photoactive component until the organic photoactive component has a water contact angle that is acceptable. Tuning the organic photoactive component until the organic photoactive component has a water contact angle that is acceptable comprises binding hydrophobic moieties to the organic photoactive component, i.e., to either the photoactive neutral molecule or the counterion of the photoactive organic salt. As described above, non-limiting examples of suitable hydrophobic moieties include —CH₃, —SH, —Cl, —F, —CCl₃, PhCl₆, -PhCl₅, —CF₃, PhF₆, -PhF₅, -PhF_{X}Cl_{y} (X=1 to 5 and Y=5-X), -PhF_{X}H_{y} (X=1 to 5 and Y=5-X), -PhCl_{X}H_{y} (X=1 to 5 and Y=5-X), PhF_{X}Br_{y} (X=1 to 5 and Y=5-X), PhF_{X}I_{y} (X=1 to 5 and Y=5-X), PhCl_{X}Br_{y} (X=1 to 5 and Y=5-X), PhBr_{X}I_{y} (X=1 to 5 and Y=5-X), PhF_{X}Cl_{y}Br_{z} (X=1 to 5, Y=5-X-Z, and Z=5-Y-X), and other fluorocarbons, polar hydrophobic groups, and non-hydrogen-bond-forming groups. Less hydrophobic moieties include —OH, —COOH, (Ph)-CH, CN, —SOO, and combinations thereof, wherein the OH, COOH, and (Ph)-CH are more wettable (hydrophilic) and/or hydrogen bonding prone relative to the remaining moieties.

In various embodiments, the method also comprises tuning the photoactive neutral organic molecule or the photoactive organic salt to have a HOMO energy of greater than or equal to about 5.0 eV to less than or equal to about 5.6 eV, such as a HOMO energy of about 5.0 eV, about 5.1 eV, about 5.2 eV, about 5.3 eV, about 5.4 eV, about 5.5 eV, or about 5.6 eV as described above.

In certain aspects, the method may further include tuning the photoactive material to have a desired absolute magnitude of binding energy, as described below.

The method also comprises disposing the organic photoactive component having a water contact angle of greater than or equal to about 65° (or other predetermined acceptable water contact angle) into a photovoltaic device. Disposing the organic photoactive component having a water contact angle of greater than or equal to about 60° into a photovoltaic device into a photovoltaic device comprises disposing the organic photoactive component having a water contact angle of greater than or equal to about 65° onto a layer of a photovoltaic device. Accordingly, in some embodiments, the method also comprises disposing a first electrode onto a substrate and disposing the organic photoactive component having a water contact angle of greater than or equal to about 60° on the first electrode as an active layer. Additional layers, as discussed herein, can also be disposed onto the device.

In some embodiments, the method further comprises encapsulating and sealing the organic photovoltaic device in an environment comprising, consisting essentially of, or consisting essentially of nitrogen gas. By an environment “consisting essentially of nitrogen,” it is meant that a small amount (for example, less than or equal to about 10 vol. %) of unavoidable impurity gases, i.e., gases other than nitrogen, may be present within the environment. The encapsulating comprises encapsulating the photovoltaic device in in an encapsulation comprising, for example, glass, cavity glass, or a plastic, each of which may be visibly transparent. The sealing comprises sealing the edges of the encapsulation with an adhesive, such as an epoxy.

With reference to FIG. 3A, a TLSC 300 according to various embodiments is shown. The TLSC 300 comprises a waveguide or substrate 302. The waveguide 302 comprises a first surface 304 that receives light, such as incident light, and an opposing second surface 306 that transmits light. The waveguide 302 also comprises edges 308. The waveguide 302 comprises a visibly transparent material.

The TLSC 300 (e.g., the entire TLSC 300 between a surface that receives direct light and a surface that transmits the light) may have any of the characteristics described above, including, but not limited to AVT, YPFD, substantially absorbent wavelengths, wavelengths at largest peak absorption, wavelength cutoffs, transmission haze, CRI, PCE, and/or LUE.

The waveguide 302 is in contact with a luminophore or waveguide redirecting material 310 (or photoactive material, or photoactive component, or plurality of luminophores), described in greater detail below. The luminophore 310 may be in contact with the waveguide 302, such as embedded within the waveguide 302, disposed directly on the waveguide 302, provided within a layer or film on the waveguide 302, or any combination thereof. The waveguide 302 may include one or more different luminophores. The TLSC 300 may include multiple waveguides 302, each with the same and/or different luminophores 310. These multiple waveguides can be coupled to the same PV cell or different PV cells (see, e.g., PV cell 326, described below) to make a multi-junction device.

The luminophore 310 may be configured to be wavelength selective. FIG. 3B shows the TLSC 300 as it receives light within a first wavelength range 320 and light within a second wavelength range 322 on the first surface 304 of the waveguide 302. The luminophore 310 absorbs at least a portion of light in the second wavelength range 322. However, the luminophore 310 does not substantially absorb the light within the first wavelength range 320, which passes through the second surface 306 of the waveguide 302. The absorbed light 322 excites the luminophore 310, which emits light 324 of a different wavelength, which is guided by the waveguide 302 to the edges 308. Therefore, the TLSC 300 harvests the light 322 and the waveguide 302 guides the light 324 emitted from the luminophore 310.

The emitted light 324 is directed to a photovoltaic (PV) cell 326 or array connected to one or more of surfaces 304, 306 (e.g., over a portion of the surface(s) 304, 306, adjacent to one or more of the edges 308) and/or edges 308 to generate electricity. Additionally or alternatively, the TLSC 300 may include a PV cell or array connected to the first surface 304, the second surface 306, and/or embedded in the waveguide 302 between the first and second surfaces 304, 306.

In at least one example embodiment, the PV cell 326 includes germanium (Ge); amorphous germanium (a-Ge); gallium (Ga); gallium arsenide (GaAs); silicon (Si); amorphous silicon (a-Si); silicon-germanium (Site); amorphous silicon-germanium (a-SiGe); gallium indium phosphide (GaInP); copper indium selenide, copper indium sulfide, or combinations thereof (CIS); copper indium gallium selenide, copper indium gallium sulfide, or combinations thereof (CICS); cadmium telluride (CdTe); perovskites (PV), such as CH₃NH₃PbI₃, CH₃NH₃PbCl₃ and CH₃NH₃PbBr₃; or any combination thereof.

The waveguide may be transparent or semi-transparent. In at least one example embodiment, the waveguide 302 is transparent. The waveguide 302 may include glass, plastic (e.g., polythethylene, polycarbonate, polymethyl methacrylate, polydimethylsiloxane, and/or polypropylene, and/or polyvinyl chloride), or any combination thereof. In at least one example embodiment, the waveguide 302 defines a thickness 328 of greater than or equal to about 50 μm (e.g., greater than or equal to about 0.1 mm, greater than or equal to about 0.3 mm, greater than or equal to about 0.5 mm, greater than or equal to about 1 mm, greater than or equal to about 2 mm, greater than or equal to about 3 mm, greater than or equal to about 5 mm, greater than or equal to about 10 mm, or greater than or equal to about 15 mm). The thickness 328 may be less than or equal to about 20 mm (e.g., less than or equal to about 15 mm, less than or equal to about 10 mm, less than or equal to about 5 mm, less than or equal to about 3 mm, less than or equal to about 2 mm, less than or equal to about 1 mm, less than or equal to about 0.5 mm, less than or equal to about 0.3 mm, or less than or equal to about 0.1 mm)

The luminophore 310 composition, concentration, molecular orientation, and/or host interaction also affect AVT, CRI, a*b*, and PCE. In at least one example embodiment, the luminophore 310 includes salts of nanoclusters (NC), cyanines, heptamethines, squaraines, BODIPY, non-fullerene acceptor(s) (NFA), halide perovskite quantum dots with counterion surface ligands, quantum dots with counterion surface ligands, or any combination thereof. In at least one example embodiment, the luminophore includes one of the following cations/ions: Cy7, Cy7m, Cy7NHS Ester, Cy5, Cy5m, Cy5NHS Ester, Cy7.5, Cy7.5m, Cy7.5NHS Ester, Cy3, Cy3m, Cy3NHS. In at least one example embodiment, the luminophore 310 is synthesized or exchanged with one of the follow counterions/anions: tetrafluoroborate, hexafluorophosphate, Δ-tris(tetrachloro-1,2-benzenediolato)phosphate(V), Δ-tris(tetrafluoro-1,2-benzenediolato)phosphate(V), Δ-tris(tetrabromo-1,2-benzenediolato)phosphate(V), Δ-tris(tetraiodo-1,2-benzenediolato)phosphate(V), Tris(pentafluoroethyl)silane, tetrakis[3,5-bis(trifluoromethyl)phenyl]borate (TFM), tetraphenylborate, tetrakis(4-fluorophenyl)borate, tetrakis(pentafluorophenyl)borate, tetrakis(pentachlorophenyl)borate, tetrakis(pentabromophenyl)borate, tetrakis(pentaiodophenyl)borate, Bis(trifluoromethanesulfonyl)imide (TFSI), Bis(fluorosulfonyl)-imide (FSI), Fluorosulfonyl(trifluoromethanesulfonyl)imide (FTFS), Trifluoromethanesulfonate (Tf), Perfluorobutanesulfonate (PFBS), bis[(pentafluoroethyl)sulfonyl]imide (BETI), 2,2,2-trifluoromethylsulfonyl-N-cyanoamide (TFSAM), 2,2,2-trifluoro-N-(trifluoromethylsulfonyl) acetamide (TSAC), nonafluorobutanesulfonate (NF), Tetracyanoborate, B(CN)₄, Dicyanamide (DCA), Thiocyanate (SCN), Cyclic perfluorosulfonylamide (CPFSA), Camphorsulfonate (CpSO₃), Tetrahalogenoferrate(III) (FeCl₃Br), Halogenchromate (CrO₃X, X=Cl, Br, I), Tetrachloroferrate (FeX₄, X=Cl, Br, I), Di(hydrogenfluoro)-fluoride ((FH)₂F), Tri(hydrogenfluoro)-fluoroide ((FH)₃F), Dihydrogen phosphate (DHP), Difluoro phosphate, Dichloro phosphate, tricyanomethanide, acetate, triflouroacetate, trichloroacetate, tribromoacetate, Si(SiCl₃)₃, and carboranes including: o-carborane, cobalticarborane (CoCB²⁻), CB₁₁H₁₂ (CBH), H(CHB₁₁Cl₁₁), B₁₂F₁₂ (FCB), C₂B₉H₁₁, HCB₁₁H₁₁, HCB₉H₉, H₂NCB₁₁H₁₁, HCB₁₁H₅Cl₆, HCB₁₁H₅Br₆, C₅N₂B₂₂H₂₅, HCB₉Cl₉, HCB₉Cl₉. Additionally or alternatively, the luminophore 310 may include photoactive materials described above in the discussion of the active layer 16.

In certain aspects, a luminophore has a water contact angle of greater than or equal to about 65° (e.g., greater than or equal to about 70°, greater than or equal to about 75°, greater than or equal to about 80°, greater than or equal to about 85°, greater than or equal to about 90°, greater than or equal to about 95°, or greater than or equal to about 100°).

In certain aspects, the luminophore includes an ion (e.g., cation and a counterion (e.g., anion). The luminophore may have an associated binding energy between the ion and counterion, as calculated according to Equation 6 and described in Example 2, below. An absolute magnitude of the binding energy between the ion and the counterion may be less than or equal to about 6.5 eV (e.g., less than or equal to about 6.25 eV, less than or equal to about 6 eV, less than or equal to about 5.75 eV, less than or equal to about 5.5 eV, less than or equal to about 5.25 eV, less than or equal to about 5 eV, less than or equal to about 4.75 eV, less than or equal to about 4.5 eV, less than or equal to about 4.25 eV, less than or equal to about 4 eV, less than or equal to about 3.75 eV, or less than or equal to about 3.5 eV). In certain aspects, the absolute magnitude of the binding energy may be greater than or equal to about 3.25 eV (e.g., greater than or equal to about 3.5 eV, greater than or equal to about 3.75 eV, greater than or equal to about 4 eV, greater than or equal to about 4.25 eV, greater than or equal to about 4.5 eV, greater than or equal to about 4.75 eV, greater than or equal to about 5 eV, greater than or equal to about 5.25 eV, greater than or equal to about 5.5 eV, greater than or equal to about 5.75 eV, greater than or equal to about 6 eV, or greater than or equal to about 6.25 eV).

The counterion may have a plurality of available proton (i.e., hydrogen) sites. For example, benzene has 6 hydrogen sites so that each site could be hydrogen bonded (—H) or halogen bonded (—X, where X=F, Cl, Br, or I). In certain aspects, a majority (i.e., greater than 50%) of the available sites are halogen bonded (single element type or a mixture of various halogen elements). In certain aspects, all of the available hydrogen sites contain instead halogen elements and the counterion may be referred to as being fully halogenated.

In various aspects, a quantum yield (QY) of the luminophore may be greater than or equal to about 10% (e.g., greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 10%, or greater than or equal to about 90%).

In certain aspects, a concentration of the luminophore 310 in the waveguide may be greater than or equal to about 0.001 mg/mL (e.g., greater than or equal to about 0.002 mg/mL, greater than or equal to about 0.005 mg/mL, greater than or equal to about 0.01 mg/mL, greater than or equal to about 0.05 mg/mL, greater than or equal to about 0.1 mg/mL, greater than or equal to about 0.2 mg/mL, greater than or equal to about 0.5 mg/mL, greater than or equal to about 1 mg/mL, greater than or equal to about 2 mg/mL, greater than or equal to about 5 mg/mL, greater than or equal to about 10 mg/mL, greater than or equal to about 15 mg/mL, greater than or equal to about 20 mg/mL, greater than or equal to about 30 mg/mL, greater than or equal to about 40 mg/mL, or greater than or equal to about 50 mg/mL). The concentration may be less than or equal to about 100 mg/mL (e.g., less than or equal to about 90 mg/mL, less than or equal to about 80 mg/mL, less than or equal to about 70 mg/mL, less than or equal to about 60 mg/mL, less than or equal to about 50 mg/mL, less than or equal to about 25 mg/mL, less than or equal to about 10 mg/mL, less than or equal to about 5 mg/mL, less than or equal to about 1 mg/mL, less than or equal to about 0.1 mg/mL, or less than or equal to about 0.01 mg/mL). In at least one example embodiment, AVT and CRI may generally decrease as concentration increases, where the rate of decrease will depend on the selective spectral harvesting range. In at least one example embodiment, |a*∥b*| may increase with concentration and then saturate or increase with concentration and then reduce with further increases in concentration. In at least one example embodiment, the LSC 300 includes a neat layer consisting of 100% luminophore. In certain aspects, the doped luminophores are uniform in luminophore distribution in the layer and are uniform, smooth, continuous, and/or substantially free of haze.

As described above, the lifetime of LSCs devices can be extended by increasing the water contact angle of the luminophore, decreasing the absolute magnitude of the binding energy of the luminophore, and/or increasing halogen content of available sites. The water contact angle can be increased by increasing the hydrophobicity of the organic photoactive component. The binding energy can be reduced by adjusting a combination of the sterics (e.g., bulkiness, coordination geometry) and degree of halogenation. Accordingly, the current technology also provides a method of fabricating an LSC having a lifetime (T₈₀ or T₅₀) of greater than or equal to about 340 hours, greater than or equal to about 500 hours, greater than or equal to about 2,000 hours, greater than or equal to about 3 months, greater than or equal to about 6 months, greater than or equal to about 5,000 hours, greater than or equal to about 9 months, greater than or equal to about 1 year, greater than or equal to about 2 years, greater than or equal to about 3 years, greater than or equal to about 4 years, greater than or equal to about 5 years, greater than or equal to about 6 years, greater than or equal to about 7 years, greater than or equal to about 8 years, greater than or equal to about 9 years, greater than or equal to about 10 years, greater than or equal to about 15 years, greater than or equal to about 20 years, greater than or equal to about 25 years, greater than or equal to about 30 years, or greater than or equal to about 50 years. Accordingly, the lifetime (T₈₀ or T₅₀) can be from greater than or equal to about 340 hours to about 50 years or more.

The method may comprise selecting luminophore, such as those described herein. The method may comprise determining a binding energy of the luminophore, such using Equation 6 and the method described in Example 2, below. The luminophore may already have an acceptable binding energy. Otherwise, the method may further include tuning the luminophore to have an acceptable binding energy. Tuning the luminophore to have an acceptable binding energy may include counterion exchange. In certain aspects, an acceptable binding energy may be defined as an absolute magnitude of the binding angle between the ion and the counterion may being less than or equal to about 6.5 eV (e.g., less than or equal to about 6.25 eV, less than or equal to about 6 eV, less than or equal to about 5.75 eV, less than or equal to about 5.5 eV, less than or equal to about 5.25 eV, less than or equal to about 5 eV, less than or equal to about 4.75 eV, less than or equal to about 4.5 eV, less than or equal to about 4.25 eV, less than or equal to about 4 eV, less than or equal to about 3.75 eV, or less than or equal to about 3.5 eV).

In certain aspects, the method may further comprise measuring a water contact angle of the organic photoactive component and determining whether the organic photoactive component has an acceptable water contact angle of greater than or equal to about 65° greater than or equal to about 70°, greater than or equal to about 80°, greater than or equal to about 90°, greater than or equal to about 95°, or greater than or equal to about 100°. An acceptable water contact angle can be predetermined.

In certain aspects, the organic photoactive component has an acceptable water contact angle, for example, a predetermined water contact angle of about 65°. When the water contact angle is not acceptable, i.e., when the water contact angle is less than about 65°, the method comprises tuning the organic photoactive component until the organic photoactive component has a water contact angle that is acceptable. Tuning the organic photoactive component until the organic photoactive component has a water contact angle that is acceptable comprises binding hydrophobic moieties to the organic photoactive component, i.e., to either the photoactive neutral molecule or the counterion of the photoactive organic salt. As described above, non-limiting examples of suitable hydrophobic moieties include —CH₃, —SH, —Cl, —F, —CCl₃, PhCl₆, -PhCl₆, —CF₃, PhF₆, -PhF₆, -PhF_{X}Cl_{y} (X=1 to 5 and Y=5-X), -PhF_{X}H_{y} (X=1 to 5 and Y=5-X), -PhCl_{X}H_{y} (X=1 to 5 and Y=5-X), PhF_{X}Br_{y} (X=1 to 5 and Y=5-X), PhF_{X}I_{y} (X=1 to 5 and Y=5-X), PhCl_{X}Br_{y} (X=1 to 5 and Y=5-X), PhBr_{X}I_{y} (X=1 to 5 and Y=5-X), PhF_{X}Cl_{y}Br_{z} (X=1 to 5, Y=5-X-Z, and Z=5-Y-X), and other fluorocarbons, polar hydrophobic groups, and non-hydrogen-bond-forming groups. Less hydrophobic moieties include —OH, —COOH, (Ph)-CH, CN, —SOO, and combinations thereof, wherein the OH, COOH, and (Ph)-CH are more wettable (hydrophilic) and/or hydrogen bonding prone relative to the remaining moieties. All the above anions are 1− except for cobalticarborane which is 2−. However, the counterion (e.g., anion) can be 1−, 2−, 3− or 4−.

The method also comprises disposing the luminophore having the acceptable binding energy and/or water contact angle into a photovoltaic device, such as by embedding the luminophore in a waveguide and/or disposing the luminophore in a layer on the waveguide. The method may further comprise coupling a PV cell to the waveguide. In certain aspects, the method further comprises encapsulating and sealing the organic photovoltaic device in an environment comprising, consisting essentially of, or consisting essentially of nitrogen gas. By an environment “consisting essentially of nitrogen,” it is meant that a small amount (for example, less than or equal to about 10 vol. %) of unavoidable impurity gases, i.e., gases other than nitrogen, may be present within the environment. The encapsulating comprises encapsulating the photovoltaic device in in an encapsulation comprising, for example, glass, cavity glass, or a plastic, each of which may be visibly transparent. The sealing comprises sealing the edges of the encapsulation with an adhesive, such as an epoxy.

Embodiments of the present technology are further illustrated through the following non-limiting example.

### Example 1

Solar energy deployment can be augmented with the use of wavelength-selective transparent photovoltaics. Moving forward, operating lifetime is an important challenge that must be addressed to enable commercial viability of these emerging technologies. Here, the lifetimes of PVs with organic near-infrared selective small molecules and molecular salts are investigated and devices featuring organic salts with varied counterions are studied. Based on the tunability afforded by anion exchange, it is demonstrated that an extrapolated lifetime of 7±2 years from continuous illumination measurements on organic salt devices held at the maximum power point. These lifetimes are compared with changes in external quantum efficiency, hydrophobicity, molecular orbital levels, and optical absorption to determine the limiting characteristics and failure mechanisms of PV devices utilizing each donor. Surprisingly, an important correlation is shown between the lifetime and the hydrophobicity of the donor layer, providing a targeted parameter for designing organic molecules and salts with exceptional lifetime and commercial viability.

### Methods

Device Fabrication: Molecular salts are synthesized as described in previous studies, such as by Suddard-Bangsund et al. (Adv. Energy Mater. 2015, 1501659), which is incorporated herein by reference in its entirety. Prior to device fabrication, glass substrates pre-patterned with 120 nm of indium tin oxide (ITO) (Xinyan Technology) are cleaned via sequential sonication in a mixture of soap and de-ionized (DI) water, pure DI water, and acetone for 5 minutes each. Substrates are then submerged in boiling isopropanol and exposed to oxygen plasma for 5 minutes each. 5 mm² devices are then deposited through a shadow mask in the following architecture: MoO₃ (Alfa Aesar) (10 nm)/Donor/Acceptor/bathocuproine (Luminescence Technology, Inc.) (BCP) (7.5 nm)/Ag (Kurt J. Lesker Co.) (80 nm). Salt device donor/acceptor layers consist essentially of CyX (y nm)/C₆₀ (MER Corp.) (40 nm), where X is the anion paired with the Cy⁺ cation and y is the donor layer thickness (12.5 nm for CyTPFB and CyTRIS, 25 nm for CyTFM, 7.5 nm for CyPF₆, and 15 nm for Cyl). Donor/acceptor layers for other devices consist essentially of ClAlPc (TCl) (15 nm)/C₆₀ (30 nm) (PHJs) or ClAlPc (11 nm)/ClAlPc:C60 (1:1 vol., 7.5 nm)/C60 (26 nm) (PMHJs). Salt layers are spin-coated in a nitrogen environment at 2000 RPM for 20 seconds from various concentrations in 3:1 vol. chlorobenzene:dichloromethane (CyTPFB) or neat chlorobenzene (other salts). All other layers are thermally deposited at 0.1 nm s⁻¹ in vacuum with a base pressure of <3×10⁻⁶ Torr. Device substrates are then edge-sealed using epoxy in nitrogen under cavity glass with an oxygen and moisture getter.

Lifetime Testing: Prior to lifetime testing, current density (J) is measured as a function of voltage (V) under illumination by a Xe arc lamp to determine the highest performing devices on each substrate for lifetime testing. Illumination intensity is calibrated to 1 sun with a NREL-calibrated Si reference cell with KG5 filter. Substrates are then loaded into testing modules equipped with temperature sensors and photodetectors and are illuminated by a sulfur plasma lamp (Chameleon) with spectrum comparable to AM1.5 between 350-820 nm. The illumination intensity at each module position is calibrated to approximately 1 sun with a NREL-calibrated Si reference cell with KG5 filter. Module temperatures are approximately 60° C. under illumination. Customized electronics (Science Wares) are utilized to hold devices at maximum power point, measure illumination intensity and mismatch corrected J-V characteristics on each device once per hour, and continuously monitor temperature on each module. Selected devices are periodically removed from the lifetime testing apparatus for external quantum efficiency (EQE) measurements, which are calibrated by a Newport-calibrated Si detector under a quartz tungsten halogen lamp.

Quantitative Lifetime Estimation: Lifetimes are defined as the time over which the power conversion efficiency (PCE) reached 80% or 50% of the initial value after any burn-in (T₈₀ or T₅₀ respectively). Lifetime tests are conducted either for 1000 hours or until all devices on a given substrate reached T₅₀. To calculate T₈₀ and T₅₀ under ambient conditions, 1-sun direct irradiance (1000 W/m²) is divided by the average global horizontal irradiance for Kansas City, Mo. (4.3 kWh/m²-day, approximately equal to the average for the United States) to calculate a time multiplier of 5.66. For devices that do not reach T₅₀ after 1000 hours of constant illumination, a linear regression is fit to normalized performance data following initial burn-in to extrapolate T₈₀ and T₅₀.

Surface and optical characterization: Contact angles are measured with a KRÜSS DSA-100 drop shape analyzer for neat (flat) donor films that are deposited on glass. AFM data are measured in contact mode for films deposited on Si substrates. Transmission is measured with a UV/VIS spectrometer without a reference sample.

### Results and Discussion

The operating lifetimes of OPV architectures are reported utilizing two classes of NIR-selective donors, solution-deposited molecular salts and vacuum-deposited small molecules, to determine the effects of donor molecular structure, morphology, molecular orbitals, and surface properties on device stability. For the molecular salts, a NIR selective heptamethine cation (Cy⁺) is paired with various anions including tetrakis(pentafluorophenyl)borate (CyTPFB), Δ-tris(tetrachloro-1,2-benzendiolato)phosphate(V) (CyTRIS), tetrakis[3,5-bis(trifluoromethyl)phenyl]borate (CyTFM), PF₆ (CyPF₆), and I (Cyl). Cy⁺ and the various anions are illustrated in FIG. 2A. Cy salts are prepared by anion exchange of the parent Cyl compound. Planar heterojunctions (PHJs) and planar-mixed heterojunctions (PMHJs) are investigated utilizing chloroaluminum phthalocyanine (ClAlPc), a NIR-selective vacuum-deposited small molecule, which has previously been shown in wavelength-selective HTPVs. The absorption spectra for all donors are shown in FIG. 2C.

PHJ and PMHJ devices are fabricated and encapsulated under nitrogen.

Four devices across at least two substrates per architecture are then tested under constant 1-sun illumination while being held at maximum power point (MPP) for 1000 hrs. MPP is focused on because it represents a realistic load placed on devices in practical applications. Moreover, surprisingly, significant differences are not observed in stability for the various architectures tested at short circuit, open circuit, and MPP as illustrated in FIGS. 3A-3C. Current-voltage characteristics are measured once per hour to extract time dependent performance parameters, resulting in only a brief pause in holding the cell at the MPP. External quantum efficiencies (EQEs) and transmission measurements are collected periodically on representative devices via brief removal from the lifetime tester. Lifetimes are typically defined as the time over which the power conversion efficiency (PCE) reaches 80% or 50% of the initial value following any burn-in (T₈₀ and T₅₀ respectively). Accelerated lifetime values are multiplied by 5.66×average hours of 1-sun illumination per day to convert from accelerated constant illumination to ambient conditions in Kansas City, Mo., which closely represents the average daily illumination in the United States (and peak power of ˜1000W/m²). Greatly enhanced measured lifetimes from seasons to years in some cases for devices tested under constant illumination and outdoors respectively have been reported. This suggests that this extrapolation can be an accurate representation of lifetime under ambient illumination.

Normalized short circuit current density (J_{sc}), V_{oc}, fill factor (FF), and PCE characteristics are shown as a function of time in FIGS. 4A-4D for small molecule donors and in FIGS. 5A-5D for molecular salt donors. Representative best lifetime data are shown in FIGS. 6A-6B for all architectures. A wide range of device lifetimes among the architectures tested are shown. For example, the ClAlPc PMHJs exhibit significantly higher stability than the ClAlPc PHJs, with a champion T₅₀ of 4380 hours compared to 270 hours, respectively. In the ClAlPc architectures, J_{sc} and FF losses dominate the performance roll-off for approximately the first 30 hours of each test, after which V_{oc} begins to decline first in the PHJs and then in the PMHJs. Surprisingly, a larger range of lifetimes is observed throughout the organic salts even though they all contain the same photoactive cation. CyTPFB devices show dramatically enhanced stability compared to the ClAlPc devices, as well as the rest of the salt devices with the best T₅₀ of 7±2 years. Salt devices with other anions exhibit comparable lifetimes to the ClAlPc PHJs, with the exception of CyTRIS (T₅₀=1740 hours). CyPF₆ devices have a T₅₀ of 280 hours, while Cyl devices exhibit a T₅₀ of 18 hours. CyTFM devices exhibit the lowest stabilities, with a best T₅₀ of only 4 hours, despite similar initial performance to CyTPFB. For the salt devices, J_{sc}, V_{oc}, and FF values simultaneously roll off within 100 hours and largely determine the overall losses in PCE, with the exception of CyTPFB. For CyTPFB devices, J_{sc} undergoes a slight burn-in over the first 10 hours of the tests before stabilizing, FF slightly rolls off after 200 hours, and V_{oc} remains essentially unchanged.

EQE data that is measured for individual devices from selected architectures during lifetime testing are shown in FIGS. 7A-7D, while optical transmission data are shown in FIGS. 8A-8C. While the ClAlPc PHJ EQE rolls off significantly as time approaches T₅₀, the EQEs for other architectures stabilize shortly after lifetime tests are started. The CyTPFB device experiences only a slight EQE roll-off of approximately 10%, correlating with the J_{sc} burn-in. Optical transmission is increased slightly over time around ClAlPc absorption wavelengths, indicating slight photobleaching, however all architectures retain apparent absorption well beyond NIR EQE losses that are observed. The losses in C₆₀ EQE suggest that the uniform losses in EQE likely indicate that these defects originate on the donor and act as recombination sites for all hole collection.

Physical properties including the HOMO and water contact angles for isolated donor and mixed ClAlPc:C₆₀ films are shown in Table 1 below. Representative photographs that are used to calculate water contact angles from selected films are shown in FIGS. 9A-9F. Co-depositing ClAlPc and C₆₀ together in a mixed layer increases the contact angle from 62±1° for neat ClAlPc to 69±2°. Interestingly, CyTPFB exhibits a contact angle of 99.8±0.4° (hydrophobic) while CyTFM has a contact angle of 58±4° (hydrophilic). CyTRIS, CyPF₆, and Cyl exhibit contact angles of 80±1°, 75±4°, and 71±2° respectively. The salt films are amorphous, each exhibit RMS roughness<1 nm, and none exhibit any significant solubility in water. AFM data shown for CyTPFB and CyTFM in FIGS. 10A-10B demonstrate no significant change in surface roughness, indicating variation in hydrophobicity is due primarily to the chemical structure of the anion.

TABLE 1
Champion device lifetimes converted to ambient illumination and
water contact angles measured from 50 nm isolated donor films.

| | | | | | Water Contact | HOMO |
|---|---|---|---|---|---|---|
| Donor | T₈₀ | | T₅₀ | | Angle [Degrees] | (eV) |
| CyTPFB | 3 | years^{a)} | 7 | years^{a)} | 99.8 ± 0.4 | 5.45 |
| CyTRIS | 340 | hours | 1740 | hours | 80 ± 1 | 4.9 |
| CyPF₆ | 60 | hours | 280 | hours | 75 ± 4 | 4.8 |
| CyI | 4 | hours | 18 | hours | 71 ± 2 | 4.6 |
| CyTFM | 1.4 | hours | 4 | hours | 58 ± 4 | 5.3 |
| ClAlPc | 30 | hours | 270 | hours | 62 ± 1 | 5.5 |
| (PHJ) | | | | | | |
| ClAlPc | 270 | hours | 4380 | hours | 69 ± 2 | 5.5 |
| (PMHJ) | | | | | | |

^{a)}Values calculated from linear extrapolation.

The deviation between ClAlPc PHJ and PMHJ stabilities is largely due to the morphology of the photoactive layers. In PMHJs, photocurrent generation is significantly enhanced and confirmed by increases in EQE. This enhancement primarily stems from a shorter length over which excitons need to diffuse before dissociation, resulting in an overall shorter exciton lifetime. Excitons in the PMHJ are therefore less likely to interact or annihilate with polarons or other excitons to form defects which act as charge traps in the bulk donor and acceptor layers. The longer exciton lifetimes in the PHJs increase the probability of these defect generating events, causing more immediate roll-offs in J_{sc} and FF. The losses in V_{oc} across both architectures can be attributed to the gradual formation of photo-activated interfacial states which also further degrade J_{sc}. Because the donor-acceptor interfacial area is considerably larger in the PMHJs than in the PHJs, longer periods of illumination may be required to form a significant concentration of interfacial states to affect the V_{oc}. As shown in bulk heterojunction architectures, PMHJ stabilities can potentially be further improved with the incorporation of additional donor and acceptor materials in the mixed layer to prevent phase separation.

The donor is the only unique material in each architecture. Changes in device stability are therefore unlikely to originate from electrode, transport, or acceptor layer degradation. Although all the devices are encapsulated in a nitrogen environment, oxygen and moisture can still be present in ppm quantities during encapsulation or leak through the seal and penetrate top electrodes to damage photoactive materials. Thus, one possible explanation for the large lifetime variation is the deepening of the donor HOMO level which could alter the generation efficiency of reactive oxygen species. Superoxides, which are formed in a charge transfer process if the HOMO is closer to the vacuum level than the oxygen ground state, can photobleach the donor material, severely limiting the lifetime of the collective device. Such a mechanism would be expected to degrade absorption with time. However, surprisingly, little correlation between HOMO and lifetime is shown in Table 1 and little reduction in the absorption efficiency in FIGS. 8A-8C. In particular, the key comparison between CyTPFB and CyTFM shows that while these two compounds have similar HOMO, similar voltage, and even similar fluorinated chemical structures, they have vastly different lifetimes. Though reactive oxygen species may still play a role in lifetime, this indicates the presence of a separate degradation mechanism.

An alternative explanation could stem from the degree of hydrophobicity (as measured by water contact angle). Indeed, in FIG. 11, lifetime versus the water contact angle is plotted for the respective donor types. The salt lifetimes correlate exponentially (linearly on a semilog plot) to water contact angle, where contact angle increases from 58±4° for CyTFM to 99.8±0.4° for CyTPFB, while lifetime increases from 4 hours to 7±2 years respectively. Additionally, the order of magnitude difference in lifetime between the ClAlPc PHJ and PMHJ, while this is largely attributed to exciton lifetime reductions, is also seemingly correlated with the difference in contact angle which could imply additional degradation mechanisms similar to the salts that are reduced as the layer becomes more hydrophobic or is reflecting a variation in the morphology (surface roughness) that results in lowered exciton lifetime.

The most striking variation is the 40° difference in water contact angle between CyTPFB and CyTFM. This is explained by the degree of functionalization of the respective anions. Polar functional groups can significantly alter the solubility of the collective salt in a given solvent. The phenyl groups present on the TFM anion are made slightly more polar by the trifluoromethyl functionalization as compared to the more symmetric distribution of fluorine atoms around the phenyl groups on the TPFB anion. Although both CyTPFB and CyTFM exhibit low water solubilities, the structure of the TFM anion may still permit chemical interactions (particularly at the C—H bonds in the anion) with water resulting in a lower contact angle. The stark differences in lifetime are then likely explained by ppm or sub-ppm levels of moisture interaction still present even in packaged devices. Differences in hydrophobicity can potentially also represent prevention of other sources of degradation such as physical repulsion of reactive species (oxygen, hydroxyl, water, and nitrogen based radical species), limit hydrogen bonding interactions, or increase inertness to interaction at the C₆₀ interface where donor-acceptor (C₆₀) adducts form under favorable interactions. The hydrophobicities of buffer and encapsulation layers have been correlated to lifetime; however, lifetime has not been connected to the active layer hydrophobicity. The design of hydrophobic photoactive materials therefore provides a key metric to identify highly stable molecular salt and non-salt devices.

For compounds that have higher degree of water solubility, water contact angle could be made with dynamic wetting measurements or correlated to other representative solvent contact angles.

This demonstrates the impact of chemical structure and morphology of NIR wavelength-selective donor materials on the lifetime of OPV devices. A series of organic small molecules and molecular salts containing a common photoactive cation with varied counterion are also systematically investigated. Studying the range of donor materials in otherwise identical architectures shows that most changes in stability are intrinsically related to the donor material and not products of acceptor, transport, or electrode layer degradation. Further, the impact of HOMO, water contact angle, and anion structure in the case of the molecular salts is evaluated, and a clear correlation between stability and hydrophobicity is displayed. Devices utilizing a hydrophobic donor layer (CyTPFB) exhibit a champion lifetime (CyTPFB) of 7±2 years, demonstrating improvement in lifetime related specifically to active layer hydrophobicity. While the hydrophobicity may be an indicator of other interactions, it nonetheless serves as a rapid indicator/screening-metric for longer lifetimes, and allows for the fabrication of stable, NIR selective donor materials that can be utilized in opaque and visibly transparent PVs.

### Example 2

Example 2 relates to enhanced lifetime of near-infrared-selective cyanine dyes in luminescent solar concentrators via counterion substitution.

Organic luminophores offer great promise for luminescent solar concentrators due to tunable absorption, strong luminescence, high solubility, and excellent wavelength-selectivity. To realize this potential, however, the lifetimes of luminophores must extend to many years under illumination. By exchanging the counterion of a heptamethine cyanine salt, we surprisingly show that the photostability and corresponding device lifetime of dilute cyanine salts can be improved by orders of magnitude from 10 hours to extrapolated lifetime of greater than 20,000 hours under illumination. To help correlate and understand the underlying mechanism, the water contact angle and binding energies of each pairing was measured and calculated. We find that increased water contact angle, and therefore increasing hydrophobicity, correlate to improved device lifetimes, while a lower binding energy between cation and anion correlates to increased lifetimes. Utilizing the binding energy formalism, we predict the stability of a new cation and experimentally verify good consistency within error. Moving forward, these factors can ultimately be used to rapidly screen and identify highly photostable salt systems for a range of energy related devices.

LSCs offer an inexpensive approach to large-area solar harvesting. LSCs comprise luminophores dispersed in a waveguiding medium, where the luminophores absorb incident solar irradiance and reemit it in all directions, as shown in FIG. 13A. Most of the emitted photons will be waveguided via total internal reflection to the edge-mounted photovoltaic PV cells, which will have a bandgap dependent on the photoluminescence (PL) of the luminophore. Due to the lack of transparent electrodes over the active layers, LSCs can be more easily designed for high-visible transparency applications like windows or mobile electronics, when compared to traditional PVs, by tuning the absorption and emission of the luminophore from the visible into the near-infrared (NIR), as shown in FIG. 13B, or ultraviolet (UV) wavelength ranges. Organic luminophores are excellent candidates to achieve high-visible transparency due to tunable absorption widths and sharp absorption cutoffs, high absorption coefficients, and high quantum yields (QY).

Heptamethine cyanines (Cy7) are a class of cyanine derivatives that are used for biomedical imaging due to their high molar extinction coefficients near the bandgap (ε>10⁵ M⁻¹ cm⁻¹), low toxicity, and relatively high QY in the NIR (˜20-35%). In general, they include a heptamethine chain contained between two indole groups and a photoinactive counterion, as shown in FIG. 13C. Despite excellent optical properties, Cy7 is often observed to suffer from low photostability with many of the demonstrated lifetime reports on the order of hours under illumination due to photobleaching. Under illumination in ambient conditions, one possible photobleaching degradation mechanism is the generation of singlet oxygen in reacting with the excited triplet states of a cyanine dye that can then further react with the polymethine chain cleaving the chain and eliminating conjugation. This low photostability has seemingly limited the potential of many cyanines as effective luminophores for power-producing LSCs because devices become limited to the lifetime of the luminophore, given that a Si edge-mounted PV cell will have a lifetime of 25 years. Thus, it is advantageous to improve the dyes photostability to take advantage of its optical properties for LSCs and transparent LSCs.

Recently, weakly coordinating anions have been shown to dramatically affect various properties such as solubility and thermal stability, as well as modulating energy levels for neat films. Weakly coordinating anions are known for being less nucleophilic than most anions due to a broader charge distribution. Moreover, Example 1 demonstrates that exchanging anions in heptamethine cyanine salts can result in extrapolated lifetimes of greater than 7 years in solid-state neat layers for organic photovoltaics without altering the bandgap. In Example 1, improved device lifetime is shown to correlate to increased water contact angle and, thus, increased hydrophobicity. However, the close-packed environment is notably different than the dilute environment that luminophores commonly experience in for LSCs, which has properties more characteristic of a frozen solution. Additionally, the role of these anions in improving the photostability of organic salts is still not well understood and it is difficult to determine how an anion will impact the salt. By understanding the properties responsible for improving photostability, anions can be predicted, designed, and rapidly screened to further improve the lifetime of these NIR dyes.

In this example, we demonstrate that the lifetime under illumination of a commercial Cy7 cation in the dilute limit of an LSC can be increased by orders of magnitude when only exchanging the anion to form a new salt compound, as shown in FIG. 13C. We evaluate the photostability through changes in luminophore absorption efficiency and the device quantum efficiency, generated photocurrent over time. Using these results, we further investigate potential correlating factors including hydrophobicity and ionic binding energy to inform selection and prediction of anions that will lead to further improved device lifetimes.

### Results and Discussion

We select a commercially available imaging Cy7 dye (Cy7 NHS ester) as the parent cation that can be representative of other cyanines. We additionally synthesize and test a second hepthamethine cyanine with simple methyl groups around the amines (Cy7m-X). The Cy7 cation is then paired with various weakly-coordinating anions as counterions including tetrafluoroborate (BF₄), tetrakis(pentfluorophenyl)borate (TPFB), hexafluorophosphate (PF₆), ΔTRISPHAT (TRIS), tetrakis(4-fluorophenyl)borate (FPhB), and tetraphenylborate (PhB). To measure the photostability and lifetime, these Cy7-X pairings are encapsulated in a N₂ environment (<1 ppm H₂O and O₂). We periodically measure device transmittance (T) and external quantum efficiency (EQE_{LSC}) to track changes in luminophore absorption and photoluminescence. The EQE is defined as the ratio of the number of generated electrons to the total number of photons incident on the LSC waveguide front surface, which helps describe the spectral contribution of the luminophores to the device photovoltaic performance over time. The EQE of an LSC is defined as follows:

EQE_{LSC}(λ)=IQE_{LSC}(λ)·η_{Abs}(λ) (2)

where η_{Abs} is the absorption efficiency and IQE_{LSC} is the internal quantum efficiency, ratio of generated electrons to the number of absorbed photons, of the LSC. This definition of EQE_{LSC} can be further defined as follows:

EQE_{LSC}(λ)=ηₑₓₜ(λ)·EQE_{PV}=(1−R(λ))·η_{PL}·η_{Trap}·η_{RA}·EQE_{PV}* (3)

where ηₑₓₜ is the external optical efficiency, R is the front-surface reflectance, η_{PL} is the photoluminescence quantum yield (QY) of the luminophore, η_{Trap} is the waveguiding efficiency, η_{RA} is the reabsorption repression efficiency—dependent on the spectral overlap of the luminophore absorption and emission—and EQE_{PV}* is the EQE of the edge-mounted PV at the emission of the luminophore.

Therefore, the IQE_{LSC} is defined:

IQE_{LSC}(λ)=(1−R(λ))·η_{PL}·η_{Trap}·η_{RA}·EQE_{PV}* (4)

Of those parameters, the reabsorption suppression and QY are luminophore properties. The others are properties of the waveguide and the edge-mounted PV, neither of which will show changes with time. Because the edge-mounted PV typically has a lifetime>20-25 years (e.g., Si), changes in EQE for an LSC will be dependent primarily on η_{Abs} and η_{PL} (or QY). There could be some improvement in reabsorption suppression (η_{RA}) as the overall absorption decreases initially because there is strong overlap between absorption and PL for organic compounds, but the losses in absorption and QY will more significantly impact the EQE over time. The generated photocurrent of the LSC (J_{SC,LSC}) can be calculated from the EQE as follows:

J_{SC,LSC}^{int}=e∫EQE(λ)S(λ)dλ (4)

where S is the incident solar photon flux on the front surface of the LSC. J_{SC,LSC}^{int} multiplied by the voltage and fill factor of the edge-mounted PV results in the power conversion efficiency (PCE) of the LSC. Thus, the PCE of an LSC is the product of the PCE of the edge-mounted PV and the optical efficiency of the LSC, which is a function of luminophore absorption, QY, and reabsorption losses in addition to LSC waveguiding efficiency and reflection. Changes in PCE over time are therefore proportional to only changes in absorption and QY through changes in the total photocurrent production. Recall that the IQE is defined as ratio of the number of generated electrons to the number of absorbed photons and is directly proportional to QY since all the other terms are nearly constant over the duration of the experiment (η_{Trap}, η_{RA}, and EQE_{PV}*). Thus, T, EQE_{LSC}, and IQE_{LSC} data are sufficient to measure the salt lifetime in an LSC.

Lifetime in PV devices can be characterized by T₅₀ or T₅₀, which represent the operational time it takes for the device to reach 80% and 50% of its maximum power output, respectively. We use the term T₅₀ interchangeably with lifetime for the remainder of this example. Through selection of anion, the lifetime of Cy7 changes by many orders of magnitude shown by normalized peak 1-T, as shown in FIG. 14A, which represents luminophore absorption. The EQE of each device, measured weekly, mirrors the trend shown in absorption loss, as shown in FIG. 14B, notably Cy7-FPhB and Cy7-PhB are excluded from EQE because they were completely photobleached within one day, as shown in FIGS. 15D-15F. The absorption and EQE peaks decay exponentially with time until they approach the 0, making the lifetime a parameter that can be reasonably forecast prior to the device reaching 50% power output. Cy7-TPFB demonstrates the highest photostability with 4230±10 hours under constant 1-sun illumination. Cy7-PF₆ also demonstrates a lifetime of greater than 1650±10 hours, which is comparable but significantly lower than Cy7-TPFB. Cy7-TRIS and Cy7-BF₄ exhibit lifetimes 190±10 hours and 120±10 hours, respectively. Finally, Cy7-PhB and Cy7-FPhB demonstrate lifetimes below 20 hours. The consistency between absorption loss and EQE loss indicate that ratio between IQE and QY is likely to be constant and that the primary degradation mechanism is bleaching of the absorption. To confirm this, we look at the IQE directly in FIG. 14C. Indeed, we find that the IQE stays constant for each material until it is fully degraded. Thus, the degradation of the luminophore and device can be adequately described by losses in absorption in these materials.

The extrapolated results are summarized in Table 2, below. The trends here for Cy7 cation are similar for the simpler Cy7m that lacks the NHS Ester group (replaced with a methyle group (see FIGS. 15A-15F). Cy7m-I has a lifetime of ˜1 day while Cy7m-TPFB has an extrapolated lifetime similar to that of Cy7-TPFB. While Example 1 has shown that counterions significantly impact the lifetime of solid-state neat-layer cyanine-salt photovoltaics, it is surprising and unexpected that such a large effect also occurs for cyanines doped in a solid matrix, without modifying or rigidifying the cyanine backbone. We can use these results to better understand the role of the anion in increasing the photostability of the cation.

TABLE 2
Extrapolated Lifetime of Each Salt. The extrapolated
lifetimes of the devices are calculated by multiplying
the lifetime under constant 1-sun illumination by 5
to account for average day-night cycles in the US.

| | | | Water Contact |
|---|---|---|---|
| Salt | T₅₀ (Hours) | T₈₀ (Hours) | Angle (°) |
| Cy7-BF₄ | 700 ± 200 | 290 ± 80 | 71 ± 0.1 |
| Cy7-PF₆ | 9,700 ± 3,000 | 3,900 ± 1,100 | 79 ± 0.1 |
| Cy7-TRIS | 1,300 ± 400 | 520 ± 150 | 51 ± 3.6 |
| Cy7-FPhB | 60 ± 20 | 22 ± 8 | 85 ± 0.1 |
| Cy7-PhB | 70 ± 30 | 30 ± 10 | 92 ± 0.4 |
| Cy7-TPFB | 24,000 ± 7,000 | 9,600 ± 2,800 | 97 ± 0.1 |

In Example 1, we found that water contact angle was the only parameter (of many investigated) that showed any correlation with the operating lifetime of the device, suggesting that increased hydrophobicity of the salt layer was indicative of improved lifetime. We tested if this macroscopic property would be consistent with lifetime differences observed in a dilute environment. FIG. 16A shows the measured water contact angles plotted against lifetime for each salt. Notably, Cy7-PhB and Cy7-FPhB showed much lower lifetimes (on the order of 10s of hours) compared to the other salts. One distinctive factor is that those anions are terminated on the phenyl rings with H rather than a halogen. When separating between fully halogen terminated and not fully halogenated anions, the halogenated anions show a trend that resembles the result in Example 1. Cy7-TRIS falls a bit out of line with result with a notably lower water contact angle. Residual tetrabutylammonium from the exchange remained in the resulting product, as shown in FIGS. 17A-17L. When initially depositing the water onto the Cy7-TRIS film, the water on the surface of the film would typically hold closer to an expected contact angle of greater than 90°, as shown in FIG. 18. However, at the time of measurement, the surface of the water would break, likely resulting from the hydrophilicity of tetrabutylammonium, and result in the smaller angle observed in the graph of FIG. 16A and shown in the accompanying picture in FIG. 16B. While the water contact angle still proves helpful in determining how some anions will compare to others, it is not a fully encapsulate all data points in a clean way.

The selected anions tested in this example are part of a class known as weakly coordinating anions, which have characteristically broad charge distributions. To characterize this, we calculate binding energies, shown in FIG. 19A, as follows:

E_{B}=E_{(cat+an)}−(E_{cat}+Eₐₙ) (6)

where E_{B} is the binding energy between Cy7 and a given anion, E_{(cat+an)} is the minimized system energy of Cy7 coordinated with the same anion, E_{cat} is the minimized energy of just Cy7, and Eₐₙ is the minimized energy of just the anion. The anion was simulated in 5 initial positions around the cation and the system was minimized to ensure that the ions were conformed suitably or optimally. FIG. 19B shows the minimum calculated binding energy plotted against device lifetime. Between anions of similar structures, there is a correlation between decreasing binding energy and increasing device lifetime. We use a linear fit on the semi-logarithmic plot to describe the relationship of binding energy to the device lifetime between anions of a similar structure—such as the phenylborate anions. The fit lines between the different structures show similar trends of increasing at a similar rate; however, some structural factor (or multiple parallel factors) are also likely at play because TPFB maintains a higher lifetime despite having a more negative binding energy than PF₆.

We further use this fitted trend to predict the lifetime of another anion: tetrakis(3,5-bis(trifluoromethyl)phenyl)borate (TFM), shown in FIG. 19C. We calculate that the binding energy of this system is approximately −5.4 eV, giving a predicted lifetime of ˜3800 hours when using the fit from TPFB, FPhB, and PhB. Cy7-TFM is then synthesized and the lifetime measured. The lifetime of a Cy7-TFM blend is 5300±1500 hours (FIG. 20), which shows remarkably close agreement (within error) to the predicted value. Using these tools, it is possible to start screening for anions leading to the highest probability of long lifetime (FIG. 19C).

We can start to use this data to better understand the role of the counterion in the photostability of the organic cation and, in turn, improve the design of anions for this purpose. From our lifetime measurements, hydrophobicity and sterics do not necessitate improved photostability as demonstrated by PhB and FPhB in comparison to BF₄ or PF₆. Additionally, the most favorable position for the counterion to position itself was always around the longer COOH-chain, closer to the more positively charged N atom. Thus, the anion is likely protecting the charge upon coordination, increasing the overall photostability.

Finally, we also add that while the water contact angle is a useful screening tool to determine photostability, it can change with cation as it does with the anion. In Example 1, Cy-TRIS displayed higher hydrophobicity and improved device lifetime compared to Cy-PF₆. In this example, however, Cy7-PF₆ performed longer than Cy7-TRIS. Thus, while the hydrophobicity and lifetime of a given anion can perform better compared to a different anion in one system, these results will also be cation dependent. Likewise for the binding energy results, it will likely require at least two data points of pairing the cation with anions to establish a frame of reference before using simulations to predict the best anion pairing. Additionally, water contact angle and binding energy are best measured separately, as the correlation between the two remains unclear (FIG. 21).

### Conclusions

In conclusion, this example demonstrates orders of magnitude increases in lifetime of luminescent cyanine salts in the dilute limit through a facile counterion exchange. The lifetime can be altered from 10s of hours to >20,000 hours, by monitoring the luminophore absorption and photocurrent generation, which can be broadly applied to other cyanine cations (FIG. 22). Through water contact angle measurements, we show a surprisingly and unexpectedly similar relationship of hydrophobicity and lifetime in the dilute state as it with neat-layer close-packed state. With DFT we calculate the binding energies of the Cy7-anion pairings and show a correlation with device lifetime. These models were then used to predict the lifetime of an additional anion with good agreement. We also showed the prediction of other potential anions that have not been synthesized. Thus, these findings provide an important step in helping organic salts produce more photostable and highly transparent LSCs.

### Materials and Methods

Materials: Cyanine7 NHS ester (Cy7) is purchased from Lumiprobe and is initially paired with tetrafluoroborate (BF₄) during synthesis. Potassium tetrakis(pentfluorophenyl)borate—here abbreviated as K-TPFB—is purchased from Boulder Scientific Company; Tetrabutylammonium Δ-tris(tetrachloro-1,2benzenediolato)phosphate(V)—abbreviated as ΔTRISPHAT-Tetrabutylammonium and further abbreviated here as TBA-TRIS, Sodium tetrakis(4-fluorophenyl)borate dihydrate—abbreviated here as Na—FPhB, Sodium hexafluorophosphate—abbreviated here as Na—PF₆, Sodium tetraphenylborate—here abbreviated as Na-PhB—are purchased from Sigma Aldrich. The Shandon Mount, the acting waveguiding media, is purchased from ThermoFisher Scientific.

Counterion Exchange: Counterion exchange is performed following the procedure described in source. The standard Cy7 salt and each counterion precursor are massed in a 1:2 molar ratio and dissolved into a solution of 6:1 volumetric ratio of dichloromethane to methanol. The solution is covered and stirred at room temperature for approximately 1 hour. The products are then passed through a silica gel column with dichloromethane. The colored solution is collected, and the solvent is evaporated until dry, and the powder product is collected.

Device Fabrication: The salts are dispersed into ethanol with a concentration around 0.125 mg/mL. These solutions are mixed with the Shandon mount with a volumetric ratio of 1:2 respectively. 3 mL of this mixture is then drop-cast onto a 2″×2″ glass substrate and left to dry for 4 hours in a N2 environment (<1 ppm O₂ and H₂O). After drying, epoxy is applied around the border of the Shandon film. An identical 2″×2″ glass piece is pressed against the epoxy, ensuring there are no air channels in the epoxy that allow for gas to reach the rest of the Shandon film. The active area inside the epoxy is masked with black paper; the epoxy is then UV-treated while the device is in N₂.

Lifetime Testing: One set of devices is kept under constant 1-sun illumination with a Chameleon Grow Systems lamp and exposed to the air. The transmission is taken more frequently at first then less frequently as clear trends begin to emerge (i.e., once a day to twice a week). The transmission (T) spectrum is taken of the TLSCs for each salt using a Perkin-Elmer Lambda 800 UV-VIS Spectrometer. For the EQE measurement, three sides of the panels are colored black with marker and then covered by black tape to reduce reflection. The uncovered side is mounted with a laser-cut silicon solar cell using index-matching gel. The EQE is measured using a monochromatic excitation source that is positionally confined to the center of the device using an optical fiber. One set of devices is kept in a N₂ environment in the dark. The EQE of each sample is taken weekly from 300-900 nm. The peaks of the EQE and 1-T were plotted against hours under illumination to show degradation of the salts vs time.

Water Contact Angle Measurements: Films of each of the salts are deposited via spincoating. Each salt is dissolved into 3:1 dichloromethane to chlorobenzene mixture at a concentration of 10 mg/mL. The solutions are deposited onto plasma-cleaned glass substrates, and the substrates were spun at 2000 rpm for 30 seconds. A drop of water is placed onto the substrate and an image was captured of the drop 10 seconds after it contacts substrate. The Krüss Drop Shape Analyzer is used measure the contact angle of the water and the salt film.

Binding Energy Calculation: A simplified cyanine molecule with the NHS Ester group removed and the ligand terminated with a carboxyl group is drawn in Materials Studio along each anion. The lowest energy conformation of each ion is calculated using the Geometric Relaxation task in the DMol3 software package of Materials Studio. LDA-PWC functional. DFT-D with OBS custom method. Fine quality setting: K-point separation 0.07 Å-1, energy cutoff 700 eV. Use symmetry. Charge adjusted to fit ion or system. Integration accuracy scf tolerance (1e-6 Ha for energy) set to Fine. Basis Set was DNP, basis file 3.5. Orbital cutoff quality set to fine. Energy tolerance for Geometric Optimization was 1e-5 Ha. Energy Task executed with each ion individually first. Each anion was put in the same simulation space as the simplified Cy7 cation. The anion is moved into five positions and manually rotated to reduce or minimize energy. Energy of system at each position is calculated. Energy of the cation and anion isolated systems are subtracted from the lowest system energy of the pairing to determine the binding energy of the system.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A solar panel comprising:
a substrate; and
a photoactive material, wherein the photoactive material includes an ion and a counterion, an absolute magnitude of a binding energy between the ion and the counterion being less than or equal to about 6.5.

2. The solar panel of claim 1, wherein the absolute magnitude of the binding energy is less than or equal to about 5.

3. The solar panel of claim 1, wherein a majority of available hydrogen sites on the counterion are halogenated.

4. The solar panel of claim 3, wherein the counterion is fully halogenated.

5. The solar panel of claim 1, wherein a water contact angle of the photoactive material is greater than or equal to about 65°.

6. The solar panel of claim 5, wherein the water contact angle is greater than or equal to about 75°.

7. The solar panel of claim 1, wherein the solar panel has a lifetime T₅₀ of greater than or equal to about 500 hours.

8. The solar panel of claim 7, wherein the lifetime T₅₀ is greater than or equal to about 5,000 hours.

9. The solar panel of claim 1, wherein the ion is heptamethine cyanine.

10. The solar panel of claim 1, wherein
the ion is selected from the group consisting of: Cy7, Cy7m, Cy7NHS Ester, Cy5, Cy5m, Cy5NHS Ester, Cy7.5, Cy7.5m, Cy7.5NHS Ester, Cy3, Cy3m, Cy3NHS, or any combination thereof, and
the counterion is selected from the group consisting of: tetrafluoroborate, hexafluorophosphate, Δ-tris(tetrachloro-1,2-benzenediolato)phosphate(V), tris(tetrafluoro-1,2-benzenediolato)phosphate(V), Δ-tris(tetrabromo-1,2-benzenediolato)phosphate(V), Δ-tris(tetraiodo-1,2-benzenediolato)phosphate(V), Tris(pentafluoroethyl)silane, tetrakis[3,5-bis(trifluoromethyl)phenyl]borate (TFM), tetraphenylborate, tetrakis(4-fluorophenyl)borate, tetrakis(pentafluorophenyl)borate, tetrakis(pentachlorophenyl)borate, tetrakis(pentabromophenyl)borate, tetrakis(pentaiodophenyl)borate, Bis(trifluoromethanesulfonyl)imide (TFSI), Bis(fluorosulfonyl)-imide (FSI), Fluorosulfonyl(trifluoromethanesulfonyl)imide (FTFS), Trifluoromethanesulfonate (Tf), Perfluorobutanesulfonate (PFBS), bis[(pentafluoroethyl)sulfonyl]imide (BETI), 2,2,2-trifluoromethylsulfonyl-N-cyanoamide (TFSAM), 2,2,2-trifluoro-N-(trifluoromethylsulfonyl) acetamide (TSAC), nonafluorobutanesulfonate (NF), Tetracyanoborate, B(CN)₄, Dicyanamide (DCA), Thiocyanate (SCN), Cyclic perfluorosulfonylamide (CPFSA), Camphorsulfonate (CpSO₃), Tetrahalogenoferrate(III) (FeCl₃Br), Halogenchromate (CrO₃X, X=Cl, Br, I), Tetrachloroferrate (FeX₄, X=Cl, Br, I), Di(hydrogenfluoro)-fluoride ((FH)₂F), Tri(hydrogenfluoro)-fluoroide ((FH)₃F), Dihydrogen phosphate (DHP), Difluoro phosphate, Dichloro phosphate, tricyanomethanide, acetate, triflouroacetate, trichloroacetate, tribromoacetate, Si(SiCl₃)₃, and carboranes including: o-carborane, cobalticarborane (CoCB²⁻), CB₁₁H₁₂ (CBH), H(CHB₁₁Cl₁₁), B₁₂F₁₂ (FCB), C₂B₉H₁₁, HCB₁₁H₁₁, HCB₉H₉, H₂NCB₁₁H₁₁, HCB₁₁H₅Cl₆, HCB₁₁H₅Br₆, C₅N₂B₂₂H₂₅, HCB₉Cl₉, HCB₉Cl₉, or any combination thereof.

11. The solar panel of claim 1, wherein the solar panel is a photovoltaic (PV) comprising:
a first electrode on the substrate;
the photoactive material; and
a second electrode, wherein the photoactive material is between the first electrode and the second electrode.

12. The solar panel of claim 1, wherein the solar panel is a luminescent solar concentrator (LSC) comprising:
a waveguide including,
the substrate,
the photoactive material in contact with the substrate; and
a photovoltaic device coupled to the substrate.

13. The solar panel of claim 12, wherein the photoactive material is embedded in the substrate, present in a layer on a surface of the substrate, or both embedded and in a layer.

14. The solar panel of claim 12, wherein the photovoltaic device is coupled to an edge surface of the substrate.

15. The solar panel of claim 1, wherein at least one of the ion and the counterion is organic.

16. A solar panel comprising:
a substrate; and
a photoactive material, wherein the photoactive material includes an ion and a counterion, a majority of available hydrogen sites on the counterion being halogenated, and the photoactive material having a water contact angle of greater than or equal to about 65°

17. The solar panel of claim 16, wherein the counterion is fully halogenated.

18. The solar panel of claim 16, wherein the water contact angle is greater than or equal to about 75°.

19. The solar panel of claim 16, wherein the water contact angle is greater than or equal to about 80°.

20. The solar panel of claim 16, wherein the solar panel has a lifetime T₈₀ of greater than or equal to about 500 hours.

21. The solar panel of claim 20, wherein the lifetime T₈₀ is greater than or equal to about 2,000 hours.

22. The solar panel of claim 16, wherein the solar panel is a photovoltaic (PV) comprising:
a first electrode on the substrate;
the photoactive material; and
a second electrode, wherein the photoactive material is between the first electrode and the second electrode.

23. The solar panel of claim 16, wherein the solar panel is a luminescent solar concentrator (LSC) comprising:
a waveguide including,
the substrate,
the photoactive material in contact with the substrate; and
a photovoltaic device coupled to the substrate.

24. A method of fabricating a luminescent solar panel, the method comprising:
selecting a photoactive material including an ion and a counterion;
determining whether a water contact angle of the photoactive material is greater than or equal to about 65°;
when the water contact angle is not greater than or equal to about 65°, tuning the photoactive material until the water contact angle is greater than or equal to about 65°; and
disposing the photoactive material having the water contact angle of greater than or equal 65° into a solar panel device,
wherein the solar panel device has a lifetime T₅₀ of greater than or equal to about 500 hours.

25. The method of claim 24, further comprising:
determining a binding energy between the ion and the counterion;
determining whether an absolute magnitude of the binding energy is less than or equal to about 6.5; and
when the absolute magnitude of the binding energy is not less than or equal to about 6.5, tuning the photoactive material until the binding energy is less than or equal to about 6.5.

26. The method of claim 25, wherein the tuning includes tuning the photoactive material until the binding energy is less than or equal to about 5.

27. The method of claim 24, wherein the tuning includes tuning the photoactive material until the water contact angle is greater than or equal to about 75°.

28. The method of claim 24, wherein the tuning includes substituting the counterion.
